(19) United States
(12) Patent Application Publication
(10) Pub. No.: US 2004/0090829 A1
(43) Pub. Date: May 13, 2004

(54) Memory card and its manufacturing method

(76) Inventors: Tomomi Miura, Akita (JP); Toru Saga, Akita (JP); Shinei Sato, Akita (JP); Takeshi Ito, Ikawa (JP)

Correspondence Address: Miles & Stockbridge, Suite 500, 1751 Pinnacle Drive, McLean, VA, 22102-3833, US

(21) Appl. No.: 10/466,806

(22) PCT Filed: Jan. 25, 2002
(86) PCT No.: PCT/JP02/00536

(30) Foreign Application Priority Data
Feb. 28, 2001 (JP) 2001-055834

(51) Int. Cl. G11C 7/00

(52) U.S. Cl. 365/200

(57) ABSTRACT

A less expensive memory card is provided. An electronic device according to the present invention comprises a substrate having wiring lines with plural external electrode terminals exposed to a first surface of the substrate, a sealing member formed of an insulating resin to cover the whole of a second surface as a back surface opposite to the first surface, and one or plural semiconductor elements covered with the sealing member and fixed to the second surface of the substrate, the semiconductor element(s) having electrodes connected electrically to the wiring lines through a connecting means. The substrate is quadrangular in shape and a card-shaped package is constituted by the substrate and the sealing member. One or plural semiconductor elements constituting a memory chip(s), as well as a control chip for controlling the memory chip(s), are fixed to the substrate to form a memory card. A direction recognizing portion is formed at edges of the substrate and the sealing member.

### FIELD OF ART

The present invention relates to an electronic device and a method of manufacturing the same. For example, the invention is concerned with a technique applicable effectively to the manufacture of a memory card which incorporates a semiconductor element (semiconductor chip) with an IC (integrated circuit) built therein.

### BACKGROUND ART

As storage mediums in digital cameras and audio players there are used memory cards named SD (Secure Digital) memory card, Memory Stick (trademark), and Multi Media Card (trademark) Of these memory cards, Multi Media Card is characteristic in that its thickness is as small as 1.4 mm or so.

In Japanese Patent Application No. 2000-22802 there is disclosed a structure of Multi Media Card according to the prior art.

In Japanese Published Unexamined Patent Application No. Hei 8(1996)-156470 there is disclosed an IC card having a card substrate which covers a main surface of an IC module.

Such memory cards as SD memory card and Memory Stick adopt a structure having a case which includes the whole of a wiring substrate with a semiconductor chip mounted thereon. On the other hand, Multi Media Card adopts a structure having a cap-shaped plastic case which covers a main surface of a wiring substrate (COB package) with a semiconductor chip mounted thereon, in order to attain a very thin structure.

A brief description will now be given about a COB package in Multi Media Card (a memory card) shown in FIGS. 43 and 44. As shown in FIG. 44, a memory card 1 has a wiring substrate 2 with plural semiconductor chips 5 mounted thereon and also has a plastic case 60 which covers the semiconductor chips 5.

As the semiconductor chips 5, memory chips 5a and a control chip 5b for controlling the memory chips 5a are fixed to the substrate 2. Although wiring on the substrate 2 is shown only partially, electrodes on the semiconductor chips 5 and wiring lines are electrically connected with each other through conductive wires 6. The semiconductor chips 5 and wires 6 provided on one surface of the substrate 2 are covered with a sealing member 3 of an insulating resin formed by molding.

A recess 70 is formed in one surface of the case 60. The recess 70 comprises a shallow recess 70a which permits the substrate 2 to be received therein and a deep recess 70b which permits the sealing member 3 to be received therein. The substrate 2 is bonded to the case 60 through an adhesive 71 interposed between a bottom of the recess and the substrate 2. In the figures, the numeral 4a denotes an external electrode terminal.

However, as shown in FIGS. 43 and 44, the COB package in the conventional Multi Media Card is of a structure having on its main surface a raised portion wherein the sealing member for sealing the semiconductor chips is formed and also having a thin substrate portion which spreads around the raised portion. Therefore, the case which covers the main surface of the COB package also has a deep recess with the sealing member received therein and a shallow recess for receiving therein the substrate portion which spreads around the sealing member. This structure has been a cause of problems involved in an assembling process for the case and the COB package and structural problems encountered in the memory card completed.

It is an object of the present invention to provide an inexpensive electronic device and a method of manufacturing the same.

It is another object of the present invention to provide an inexpensive memory card and a method of manufacturing the same.

The above and other objects and novel features of the present invention will become apparent from the following description and the accompanying drawings.

### DISCLOSURE OF THE INVENTION

Typical modes of the present invention as disclosed herein will be outlined below.

(1) A memory card having a first surface and a second surface as a back side of the first surface, the memory card comprising:

a wiring substrate having a main surface and a back surface;

a plurality of external electrode terminals formed on the back surface of the wiring substrate;

a plurality of wiring lines formed on the main surface of the wiring substrate;

a semiconductor element disposed on the main surface of the wiring substrate and connected electrically to the plural external electrode terminals through the plural wiring lines; and

a sealing member formed of an insulating resin on the back surface of the wiring substrate to cover the semiconductor element,

wherein the plural external electrode terminals and the back surface of the wiring substrate are exposed to the first surface of the memory card, and

wherein the sealing member is exposed to the second surface of the memory card.

Such a memory card is manufactured by a method comprising the steps of:

(a) providing a wiring substrate, the wiring substrate having unit substrate areas over a main surface thereof and a plurality of external electrode terminals on a back surface thereof;

(b) arranging semiconductor chips on the unit substrate areas and connecting the semiconductor chips electrically to the plural external electrode terminals;

(c) forming a sealing member for sealing the semiconductor chips on the unit substrate areas and also on the main surface portion of the wiring substrate located around the unit substrate areas;

(d) cutting the sealing member and the wiring substrate simultaneously at positions between the unit substrate areas and the surrounding portions to afford individual pieces, the individual pieces each comprising the wiring substrate of the associated unit substrate area, the sealing member on the unit substrate area, the semiconductor chip on the unit substrate area, and the associated plural external electrode terminals;

(e) providing a case having a recess; and

(f) bonding the sealing member to a bottom of the recess and fixing each of the individual pieces to the interior of the recess.

### BRIEF DESCRIPTION OF THE DRAWINGS

FIG. 1 is a schematic sectional view of a memory card according to an embodiment (first embodiment) of the present invention;

FIG. 2 is a bottom view showing a bottom of the memory card of the first embodiment;

FIG. 3 is a perspective view of the memory card of the first embodiment;

FIG. 4 is a perspective view of the memory card of the first embodiment, showing a state in which the memory card has been turned upside down;

FIG. 5 comprises sectional views, etc., showing manufacturing steps for the memory card of the first embodiment;

FIG. 6 is a bottom view of a matrix substrate used in manufacturing the memory card of the first embodiment;

FIG. 7 is a schematic front view of the matrix substrate;

FIG. 8 is a schematic plan view showing a state of semiconductor elements mounted on each unit substrate area in manufacturing the memory card of the first embodiment;

FIG. 9 is a schematic sectional view showing a state of forming a mold member on one surface of the matrix substrate in manufacturing the memory card of the first embodiment;

FIG. 10 is a schematic view as seen from an underside of the matrix substrate, showing in what state a molding resin is fed in manufacturing the memory card of the first embodiment;

FIG. 11 is a schematic diagram showing another substrate cutting method in manufacturing the memory card of the first embodiment;

FIG. 12 is a schematic sectional view of a memory card according to another embodiment (second embodiment) of the present invention;

FIG. 13 is a perspective view of a memory card according to a further embodiment (third embodiment) of the present invention, showing a state in which the memory card has been turned upside down;

FIG. 19 is a schematic sectional view of the memory card of the third embodiment, showing a state in which the memory card has been turned upside down;

FIG. 15 is a bottom view showing a matrix substrate used in manufacturing the memory card of the third embodiment;

FIG. 16 is a sectional view showing manufacturing steps for the memory card of the third embodiment;

FIG. 17 is a sectional view of a memory card according to a still further embodiment (fourth embodiment) of the present invention, showing a state in which the memory card has been turned upside down;

FIG. 18 is a bottom view of the memory card of the fourth embodiment;

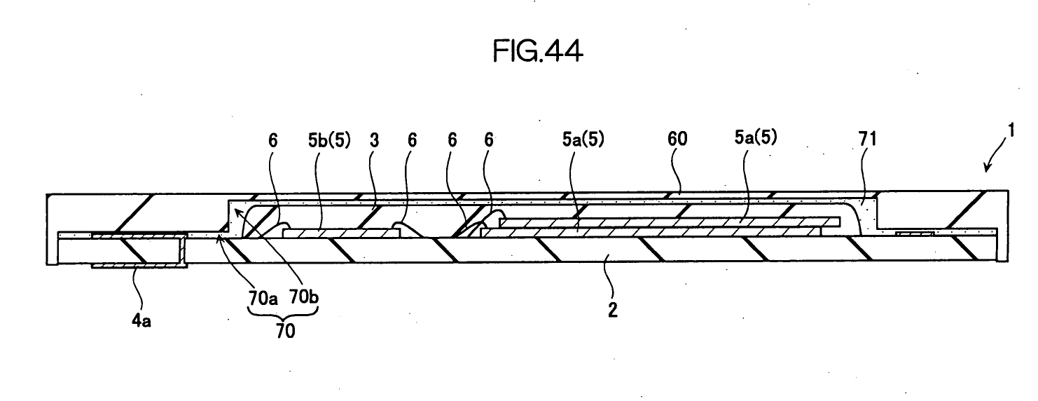

FIG. 19 is a perspective view showing in what state a semiconductor element is mounted in manufacturing the memory card of the fourth embodiment;

FIG. 20 is a partial sectional view showing an example of a mounted state of a semiconductor element in manufacturing the memory card of the fourth embodiment;

FIG. 21 is a partial sectional view showing another example of a mounted state of a semiconductor element in manufacturing the memory card of the fourth embodiment;

FIG. 22 is a sectional view of a memory card according to a sectional view of a memory card according to a still further embodiment (fifth embodiment) of the present invention, showing a state in which the memory card has been turned upside down;

FIG. 23 is a bottom view of the memory card of the fourth embodiment;

FIG. 24 is a perspective view of a memory card according to a still further embodiment (sixth embodiment) of the present invention, showing a state in which the memory card has been turned upside down;

FIG. 25 is a sectional view of the memory card of the sixth embodiment, showing a state in which the memory card has been turned upside down;

FIG. 26 is a sectional view showing manufacturing steps for the memory card of the sixth embodiment;

FIG. 27 is a perspective view showing in what state a COB package is mounted to a case in manufacturing the memory card of the sixth embodiment;

FIG. 28 is a perspective view of a memory card according to a still further embodiment (seventh embodiment) of the present invention, showing a state in which the memory card has been turned upside down;

FIG. 29 is a sectional view of the memory card of the seventh embodiment, showing a state in which the memory card has been turned upside down;

FIG. 30 is a sectional view showing manufacturing steps for the memory card of the seventh embodiment;

FIG. 31 is a perspective view showing in what state a COB package is mounted to a case in manufacturing the memory card of the seventh embodiment;

FIG. 32 is a sectional view of a memory card according to a modification of the seventh embodiment, showing a state in which the memory card has been turned upside down;

FIG. 33 is a bottom view of the memory card of the modification of the seventh embodiment;

FIG. 34 is a bottom view showing a back surface of a memory card according to a still further embodiment (eighth embodiment) of the present invention;

FIG. 35 is a sectional view of the memory card of the eighth embodiment, showing a state in which the memory card has been turned upside down;

FIG. 36 is a sectional view of a memory card according to a still further embodiment (ninth embodiment) of the present invention, showing a state in which the memory card has been turned upside down;

FIG. 37 is a bottom view of the memory card of the ninth embodiment;

FIG. 38 is a sectional view showing steps from chip bonding to wire bonding in manufacturing a COB package as a component of the memory card of the ninth embodiment;

FIG. 39 is a sectional view showing states at various stages of transfer molding in manufacturing the COB package as a component of the memory card of the ninth embodiment;

FIG. 40 is a sectional view showing states of various stages of dicing for a matrix substrate used in manufacturing the COB package as a component of the memory card of the ninth embodiment;

FIG. 41 is a bottom view of the matrix substrate used in manufacturing the memory card of the ninth embodiment of the present invention;

FIG. 42 is a perspective view showing in what state the COB package is mounted in manufacturing the memory card of the ninth embodiment;

FIG. 43 is a plan view of a memory card proposed by applicants in the present case; and

FIG. 44 is a sectional view taken along line A-A in FIG. 43.

### BEST MODE FOR CARRYING OUT THE INVENTION

The present invention will be described in more detail hereinunder with reference to the accompanying drawings. In all of the drawings for explaining embodiments of the present invention, components having the same functions are identified by like reference numerals, and repeated explanations thereof will be omitted.

### First Embodiment

In this first embodiment, reference will be made to an example in which the present invention is applied to a memory card, the memory card having a substrate on which one or plural semiconductor elements constituting memory chips are mounted and on which is also mounted a control chip for controlling the memory chip(s). The semiconductor element as a memory chip carries thereon, for example, a flash memory [Flash Memory EEPROM (Electrically Erasable Programmable Read Only Memory)] and constitutes a Multi Media Card having a large capacity of 32 MB or 64 MB for example.

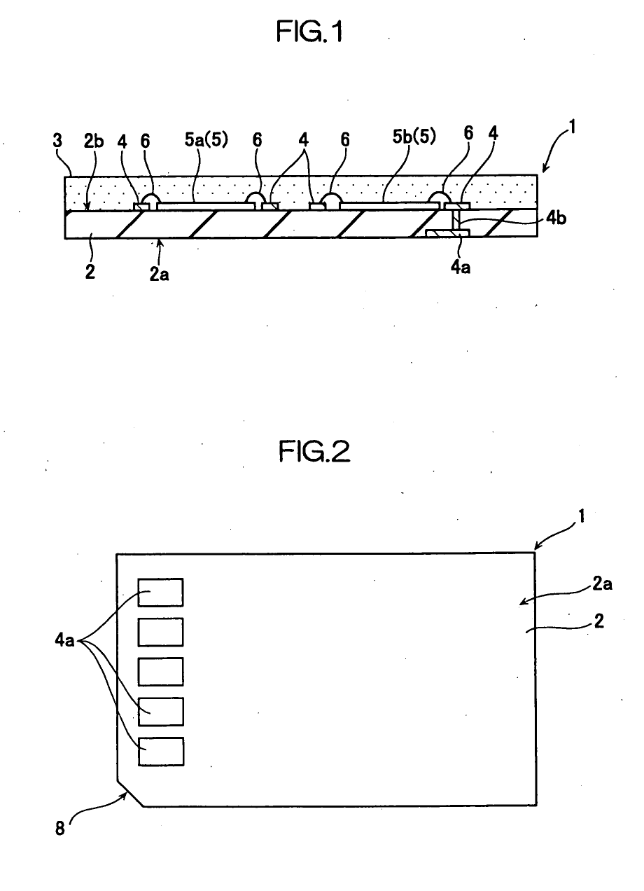

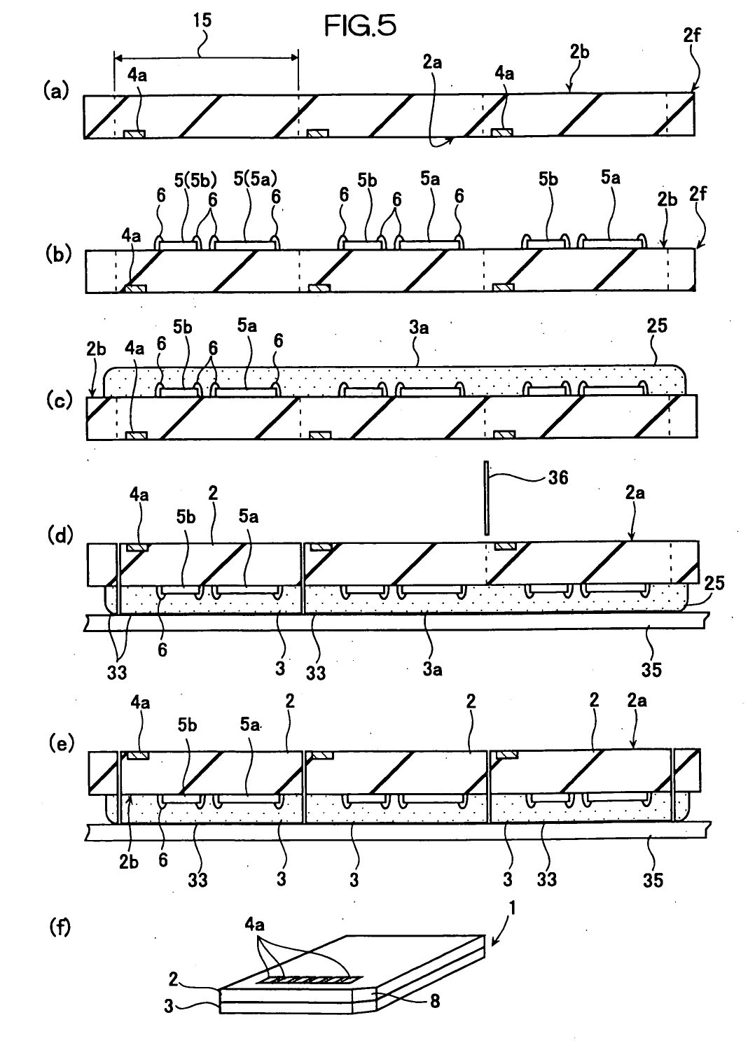

FIGS. 1 to 10 illustrate a memory card according to an embodiment (first embodiment) of the present invention, of which FIGS. 1 to 4 illustrate an appearance and a sectional structure of the memory card and FIGS. 5 to 10 are concerned with the manufacture of the memory card.

In appearance, the memory card of the first embodiment, indicated at 1, is made up of a quadrangular substrate 2 and a sealing member 3 which is formed laminationwise on one surface (e.g., a second surface 2b) of the substrate 2. The sealing member 3 is formed by transfer molding throughout the whole of the second surface 2b of the substrate 2 with a uniform thickness. For example, the sealing member 3 is formed of an epoxy resin.

The size of the memory card 1 is, for example, 32 mm long, 24 mm wide, and 1.4 mm thick, in which the thickness of the substrate 2 is 0.6 mm, and hence the thickness of the sealing member 3 is 0.8 mm.

The substrate 2 is constituted by a glass fabric-based epoxy resin substrate for example and wiring lines 4 are formed not only on its surface and back surface but also in the interior thereof. On a first surface 2a as a back side opposite to the second surface there are formed external electrode terminals 4a by wiring lines 4. The external electrode terminals 4a are arranged along one side of the substrate 2, serving as external electrode terminals of the memory card 1. For example, when the memory card 1 is inserted into a slot of a digital camera, the external electrode terminals 4a are brought into contact with electrode terminals disposed in the slot.

The external electrode terminals 4 are electrically connected to the wires 4 on the second surface through conductors 4b which are wires laid into through holes extending through the substrate 2.

Semiconductor elements 5 are fixed to the first surface 2a of the substrate 2 through an adhesive (not shown). When forming the wiring lines on the second surface 2b of the substrate 2, semiconductor elements mounting pads may be formed using the material of the wiring lines and the semiconductor elements 5 may be formed on the pads through an adhesive.

For example, as the semiconductor elements 5, a memory chip 5a and a control chip 5b for controlling the memory chip 5a are fixed onto the substrate 2. Electrodes (not shown) are formed on upper surfaces of the semiconductor elements 5. The electrodes and predetermined wiring lines 4 extending around the semiconductor elements 5 are electrically connected with each other through wires 6. For example, gold wires are used as the wires 6.

The memory card 1 is of a structure in which the semiconductor elements 5 are mounted on the second surface 2b of the substrate 2 and the second surface 2b is covered with the seal member 3. This structure is a so-called COB package structure.

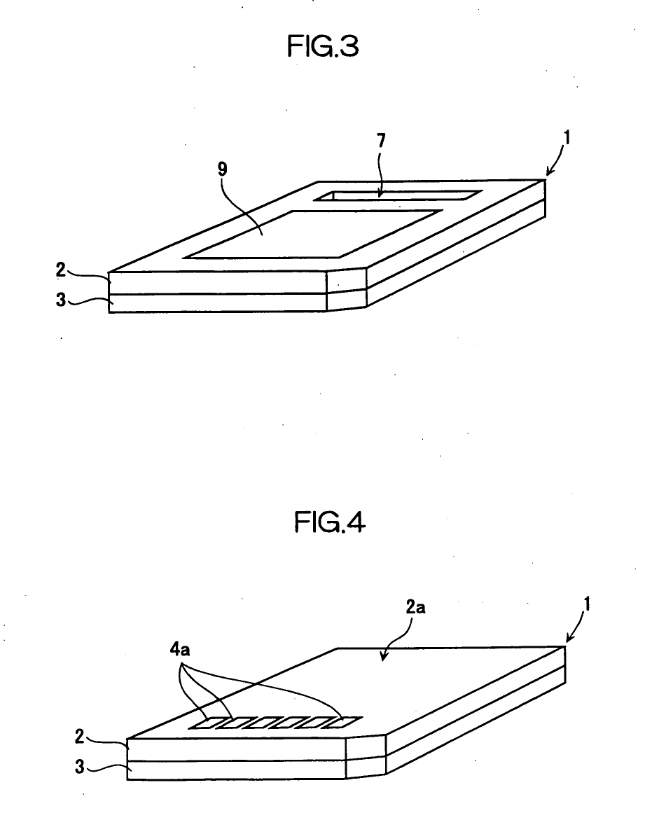

The sealing member 3 is formed by transfer molding. In this transfer molding, as shown in FIG. 3, a groove 7 of an arcuate section is formed along a short side opposite to the side where the external electrode terminals 4a are formed. The groove 7 is used for drawing out the memory card 1 after having been inserted into the slot. After the use of the memory card 1, the user of the card can hook his or her finger tip or pawl to an edge of the groove 7 and draw out the memory card 1 from the slot.

The memory card 1 is cut off obliquely at one corner of its front end to be inserted into the slot, to form a direction recognizing portion 8. Further, a seal 9 describing the function of the memory card 1 and product contents is affixed to a flat surface of the sealing member 3.

Next, with reference to FIGS. 5 to 10, a description will be given below about how to fabricate the memory card 1 of this first embodiment. FIGS. 5(a) to 5(f) are sectional views, etc. showing manufacturing steps for the memory card, of which FIG. 5(a) illustrates a matrix-shaped substrate (“matrix substrate” hereinafter) step, FIG. 5(b) illustrates a chip bonding step, FIG. 5(c) illustrates a molding step, FIGS. 5(d) and 5(e) illustrate a matrix substrate separating step, and FIG. 5(f) illustrates a direction recognizing portion forming step.

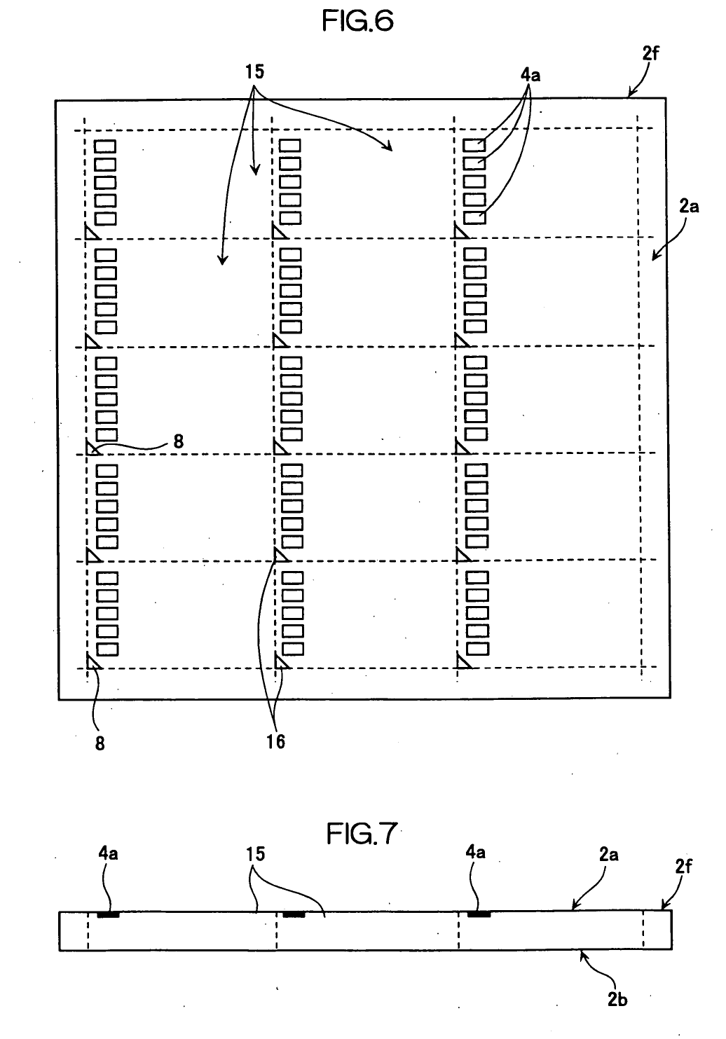

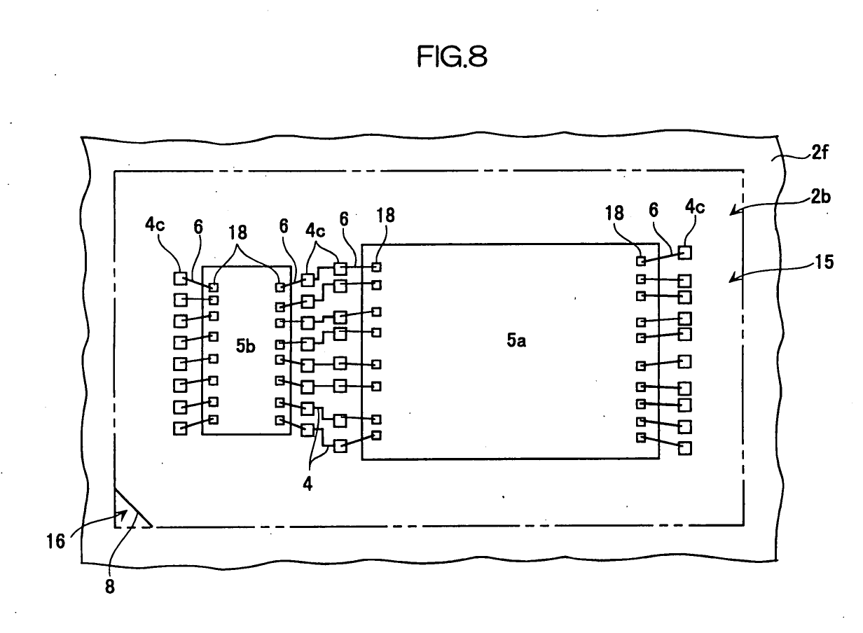

First, as shown in FIGS. 6 and 7, a matrix substrate 2f is provided. FIG. 6 shows a state in which the matrix substrate 2f has been turned upside down, i.e., a bottom view of the matrix substrate 2f, and FIG. 7 is a schematic front view of the matrix substrate.

The matrix substrate 2f is constituted by a glass fabric-based epoxy resin wiring substrate and with unit substrate areas 15 being formed thereon lengthwise and crosswise. In the figures, the areas defined by dotted line frames represent the unit substrate areas 15, which are a structural portion of the substrate 2. Semiconductor elements are mounted in each of the unit substrate areas 15 of the matrix substrate 2f and wire bonding is applied to each predetermined portion. Further, a mold member is formed so as to cover all the unit substrate areas 15 by transfer molding and thereafter the matrix substrate 2f and the mold member are cut along the dotted lines for separation into each unit substrate area 15. In this way there are fabricated a large number of memory cards 1.

The matrix substrate 2f used in this embodiment has a total of fifteen unit substrate areas 15 consisting of three columns and five rows. The structure of each unit substrate area 15 is of the substrate 2 already described. Therefore, the thickness of the matrix substrate 2f is 0.8 mm and each unit substrate area 15 is in the shape of a rectangle having a length of 32 mm and a width of 24 mm. In FIG. 6, since the first surface 2a is shown, there appear the external electrode terminals 4a of each unit substrate area 15.

In one corner of each unit substrate area 15 is formed a through hole 16 by punching. The through hole 16 is in the shape of a right-angled triangle and its slant face portion forms the direction recognizing portion 8 of the memory card 1.

The matrix substrate 2f is a glass fabric-based epoxy resin wiring substrate of a multi-layer structure though this does not constitute a limitation. Since each unit substrate area 5 corresponds to the substrate 2 described above, wiring lines are formed not only on both surface and back surface but also in the interior, provided the wiring lines are here omitted.

Chip bonding is performed for the matrix substrate 2f to fix the semiconductor elements 5, as shown in FIGS. 5(b) and 8. As the semiconductor elements 5, a memory chip 5a and a control chip 5b for controlling the memory chip 5a are fixed. The semiconductor elements 5 are fixed to the matrix substrate 2f through an adhesive though not shown. In forming wiring lines on the second surface 2b of the matrix substrate 2f, semiconductor elements mounting pads may be formed using the material of the wiring lines and the semiconductor elements may be formed on the pads through an adhesive. Electrodes are formed on the surfaces of the semiconductor elements 5 thus mounted, though not shown. The thickness of each semiconductor element is 0.28 mm or so.

Next, as shown in FIG. 8, electrodes 18 on each semiconductor element 5 and wire bonding pads 4c as wiring portions on the surface of the matrix substrate 2f are connected together using conductive wires 6. For example, the wires 6 are gold wires about 27 μm in diameter. The height of the wires 6 which connect the semiconductor elements 5 and the wiring lines is controlled low so that the wires 6 are sure to be covered with a mold member to be formed in the next step. The connecting means for connecting the electrodes 18 on the semiconductor elements 5 with the wiring lines may be of another construction.

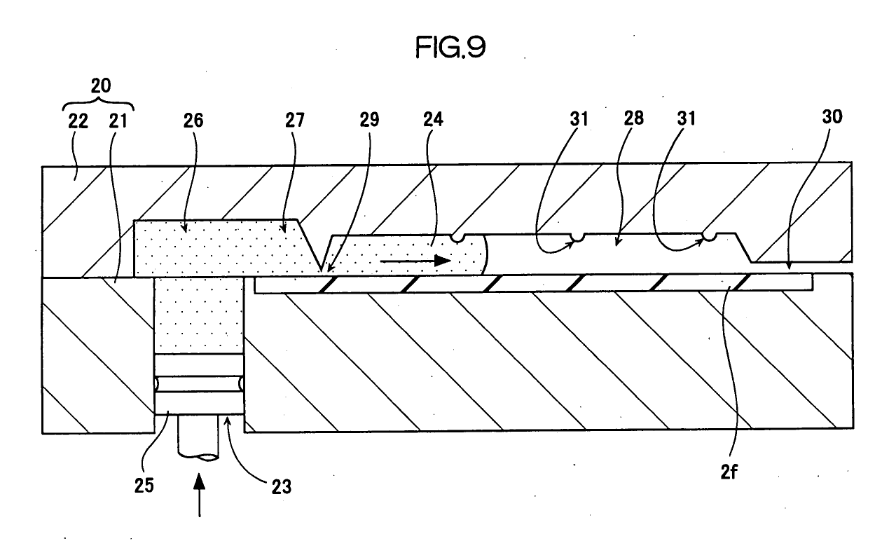

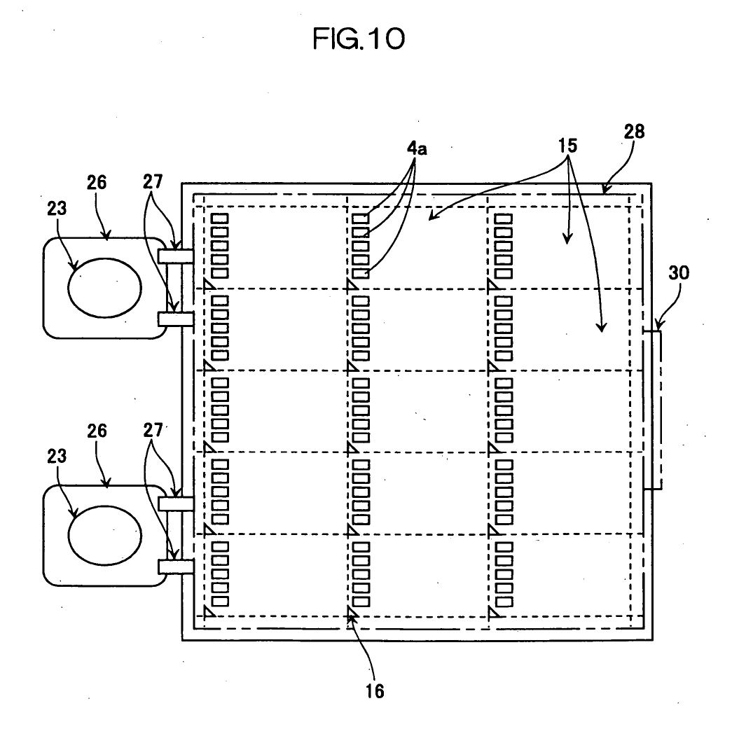

Next, as shown in FIG. 5(c), a mold member 3a (sealing member 3) of a predetermined certain thickness is formed on the second surface 2b of the matrix substrate 2f by transfer molding. For example, the mold member 3a is formed to a thickness (height) of 0.6 μm using an epoxy resin. FIG. 9 is a schematic sectional view showing a state in which the mold member is formed on one surface of the matrix substrate and FIG. 10 is a schematic diagram as seen from an underside of the matrix substrate, showing in what state resin is fed in molding.

As shown in FIG. 9, the matrix substrate 2f having been subjected to wire bonding is clamped between a lower mold 21 and an upper mold 22 of a molding die 20, then resin tablets are placed into pots 23 formed in the lower mold 21, and resin 24 which was melted with the heat of heaters (not shown) built in the lower mold 21 and the upper mold 22 is fed by a push-up motion of plungers 25 into culls 26 formed in the upper mold 22. Runners 27 extend from the culls 26, as shown in FIG. 10. The runners 27 are connected through gates 29 to a cavity 28 which has been formed by the clamping with the lower and upper molds 21, 22. The cavity 28 is formed in a size which covers all the unit substrate areas 15 of the matrix substrate 2f.

In the molding die 20 used in this first embodiment, two pots 23 are provided and two runners 27 extend from each cull 26 and communicate with a single cavity 28. In the cavity 28 is formed an air vent 30 for conducting air to the exterior of the cavity which air is forced out with the resin 24 fed into the cavity. The upper mold 22 is provided with ridge portions 31 each for forming the groove 7 of the memory card 1.

Therefore, as shown in FIG. 9, after the matrix substrate 2f has been held by clamping of the molding die 20, preheated resin tablets are put into the pots 23 and molten resin is poured into the cavity 28 by a push-up motion of the plunger 25 to form such a mold member 3a (sealing member 3) as shown in FIG. 5(c). FIG. 5(c) is a sectional view showing the matrix substrate 2f which has been taken out from the molding die 20.

Next, as shown in FIGS. 5(d) and (e), the matrix substrate 2f is fixed onto a stage 35 of a dicing machine (not shown) using an adhesive 33 which can be later removed easily and is thereafter diced with a rotating dicing blade 36 (for example, thickness 200 μm). FIG. 5(d) and (e) show a state in which the matrix substrate 2f is cut crosswise (in the width direction of the memory card 1). After the crosswise cutting is over, the stage 35 is turned 90°, followed by cutting lengthwise (in the length direction of the memory card 1). As a result, there nearly is completed a memory card 1 of a structure in which the sealing member 3 is affixed to the second surface 2b of the substrate 2. The cutting is performed by a method using such a dicing blade 36 as shown in FIG. 5 or by a method of cutting predetermined areas or the whole area with use plural dicing blades.

Then, one corner of each of the resulting rectangular pieces, namely, each of the sealing member portions provided with through holes 16 in the state of the matrix substrate 2f, is cut along the associated direction recognizing portion 8 to afford a memory card 1 having the direction recognizing portion (index) 8, as shown in FIG. 5(f). A seal 9 is affixed to the second surface 2b of the substrate 2 of the memory card 1, whereby the memory card 1 becomes employable.

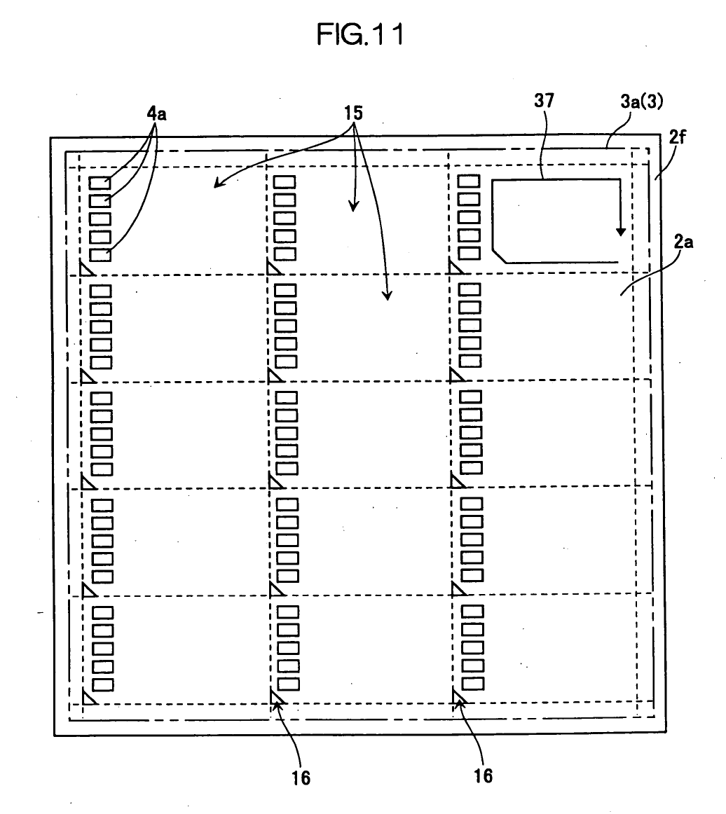

The cutting of the mold member 3a (sealing member 3), namely, the separation of each unit substrate area 15, may be done by a method other than the method using the dicing blade. For example, there may be adopted a method wherein a rotating shearing edge of a rooter (end mill) is moved along a contour line of a memory card as product to cut the mold member 3a and the matrix substrate 2f, as indicated with arrow 37 in FIG. 11.

In this case, the direction recognizing portion (index) 8 of the memory card 1 can be formed by cutting with the rooter. According to the cutting operation with the rooter, in comparison with dicing, a simultaneous cutting operation can be done in the matrix substrate dividing step into individual memory cards 1 even at portions not connected through straight lines with patterns of adjacent memory cards 1 such as the direction recognizing portions (indexes) 8.

According to this first embodiment there are obtained the following effects.

(1) Predetermined semiconductor elements 5 are mounted on the unit substrate areas 15 provided on one surface of the matrix substrate 2a, followed by block molding, and thereafter the matrix substrate 2f is cut lengthwise and crosswise together with the mold member 3a, whereby the electronic device (memory card) can be produced. Therefore, the number of manufacturing steps becomes smaller than that of the manufacturing steps heretofore adopted in the manufacture of this type of products, and hence it is possible to reduce the cost of the electronic device (memory card).

(2) In a memory card 1 not having a case, the area which permits mounting of semiconductor elements on the substrate becomes wider and the thickness of the molding resin becomes larger. Therefore, not only it becomes possible to mount larger sizes of semiconductor elements 5 but also it becomes easier to effect stacking of semiconductor elements 5. Consequently, it becomes possible to attain high function and high capacity of the memory card 1.

(3) The substrate 2 having wiring lines can be used as one constituent of a package and the electrodes 4a formed on one surface of the substrate 2 which is exposed can be used as they are as external electrode terminals 4a in the electronic device (memory card).

### Second Embodiment

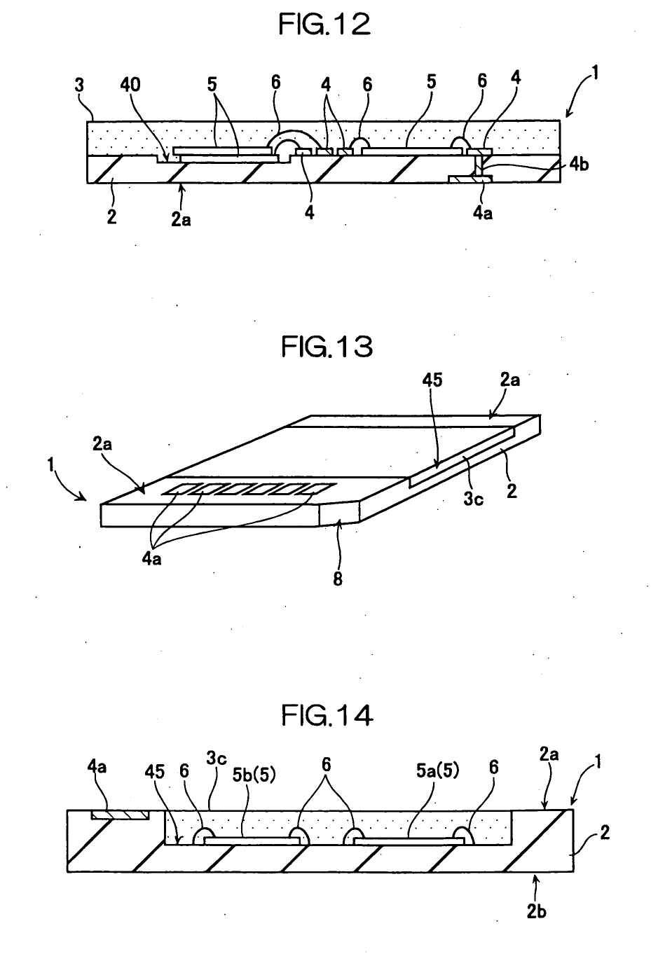

FIG. 12 is a schematic sectional view of a memory card according to another embodiment (second embodiment) of the present invention. In this second embodiment, the semiconductor element fixing area for fixing therein of a semiconductor element 5 on a substrate 2 as in the previous first embodiment is formed as a recess 40, and a semiconductor element 5 is fixed onto a semiconductor element 5 fixed to the bottom of the recess, as shown in FIG. 12.

Also in the upper semiconductor element 5 it is necessary that its electrodes be connected to wiring lines on the substrate 2. To meet this requirement, the upper semiconductor element is superimposed and fixed onto the lower electrode in a displaced manner so that electrodes on the lower semiconductor element are exposed. After chip bonding, the electrodes on the semiconductor elements 5 are connected through wires 6 to wiring lines 4 on the substrate 2. Unlike the case illustrated in FIG. 12, the wiring lines 4 (wire bonding pads) with wires 6 connected thereto may be formed on the bottom of the recess 40 to which the lower semiconductor element 5 is fixed.

In this second embodiment, one or more semiconductor elements 5 are fixed stackedly onto the semiconductor element 5 fixed to the substrate 2. By stacking semiconductor elements 5 in multiple stages it is possible to attain a high function of the memory card (electronic device). Further, by stacking memory chips as semiconductor elements 5 in multiple stages and thereby increasing the number of chips, it is possible to achieve a large capacity of memory.

### Third Embodiment

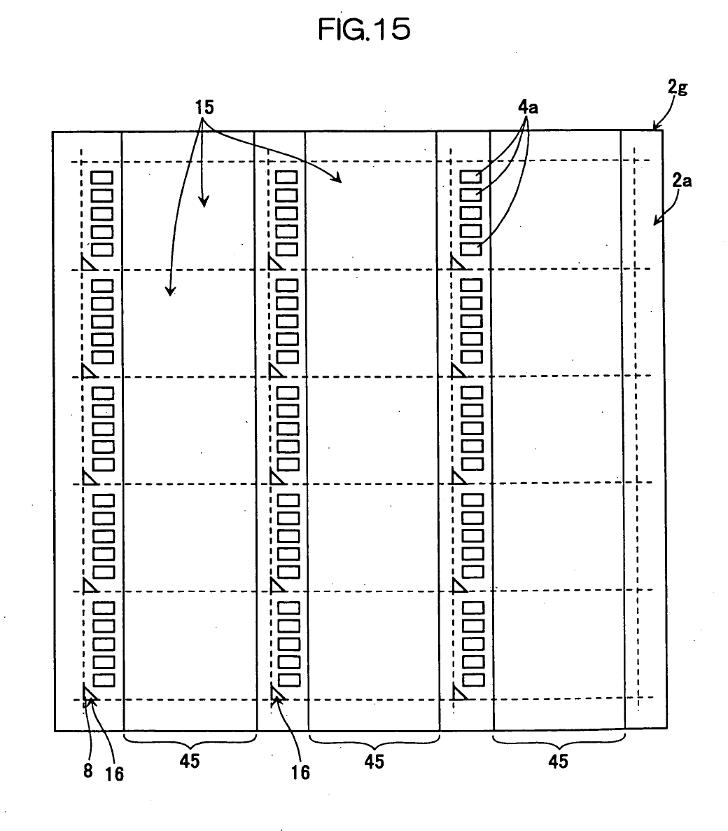

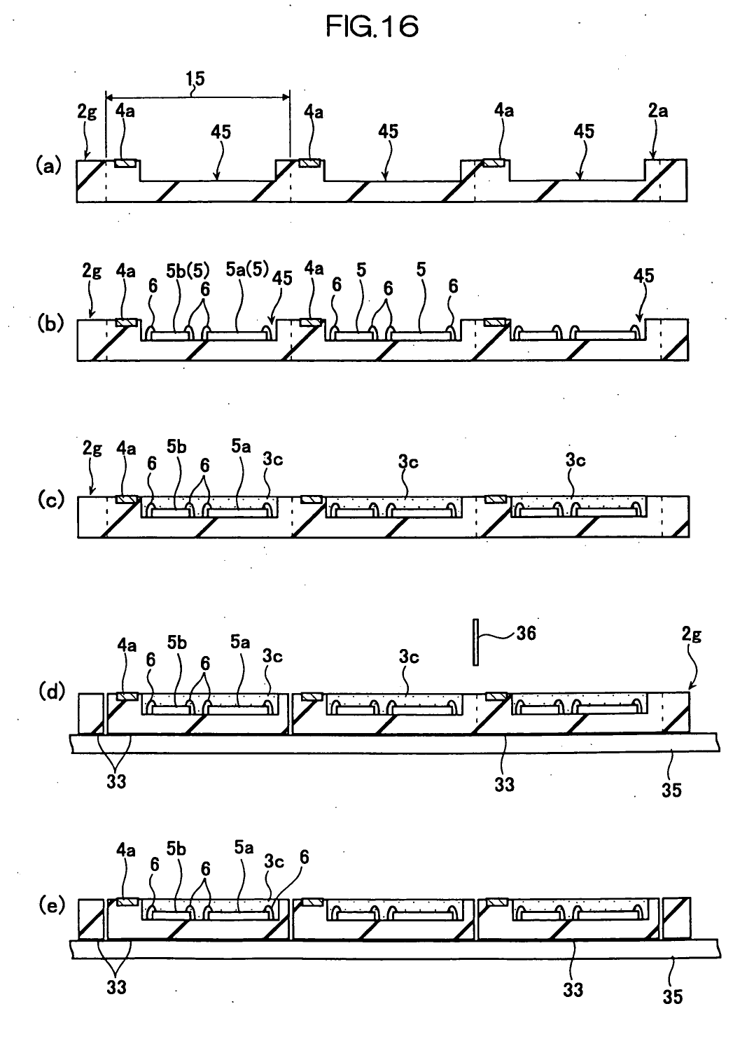

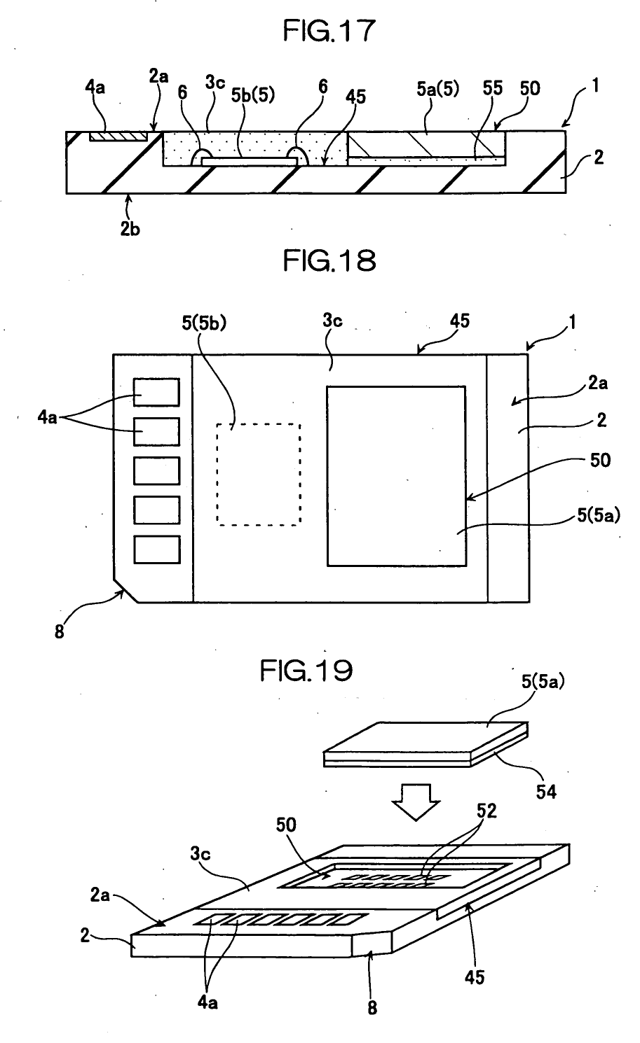

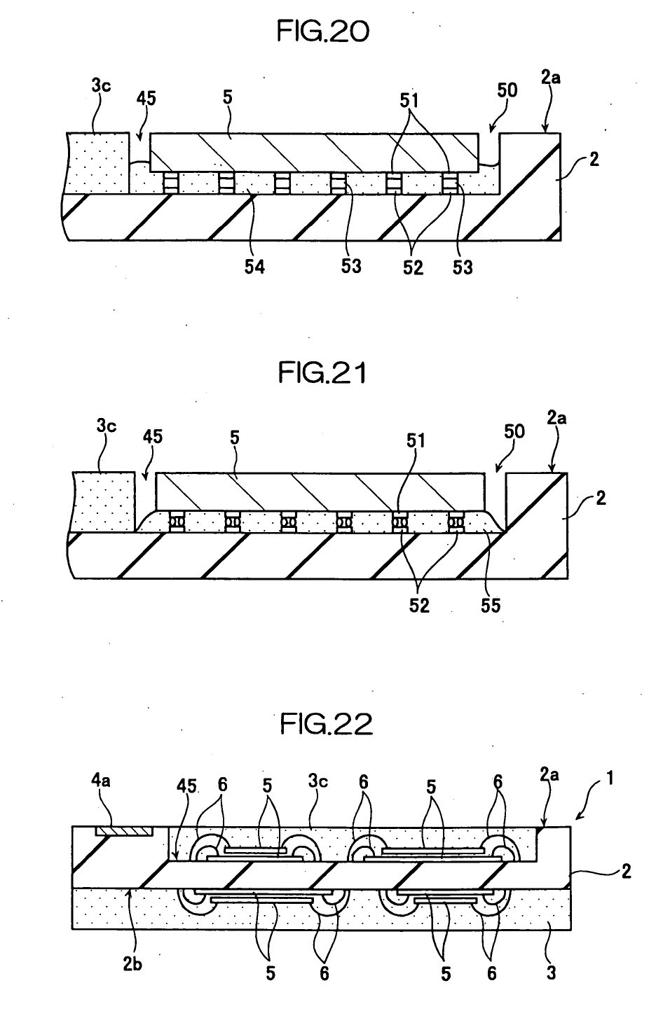

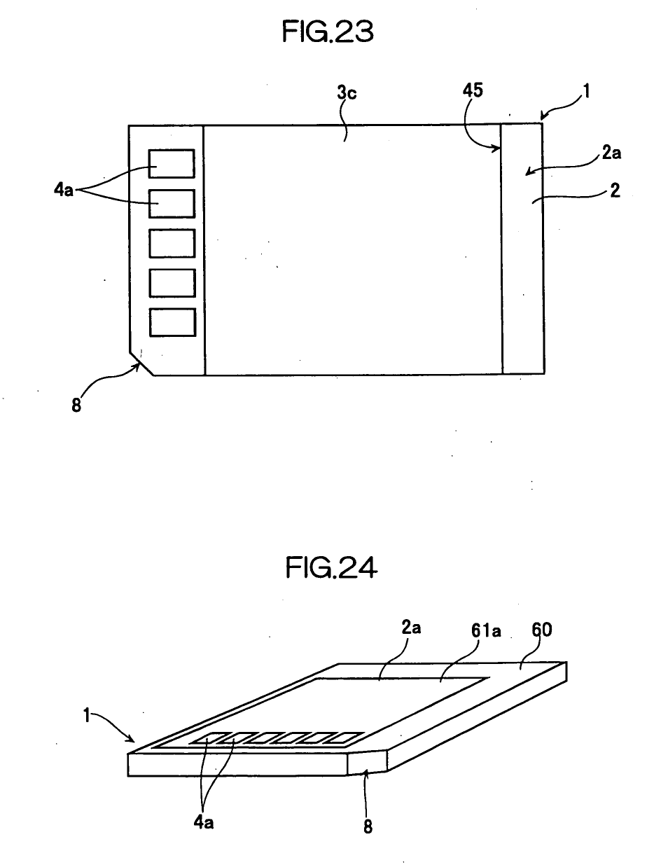

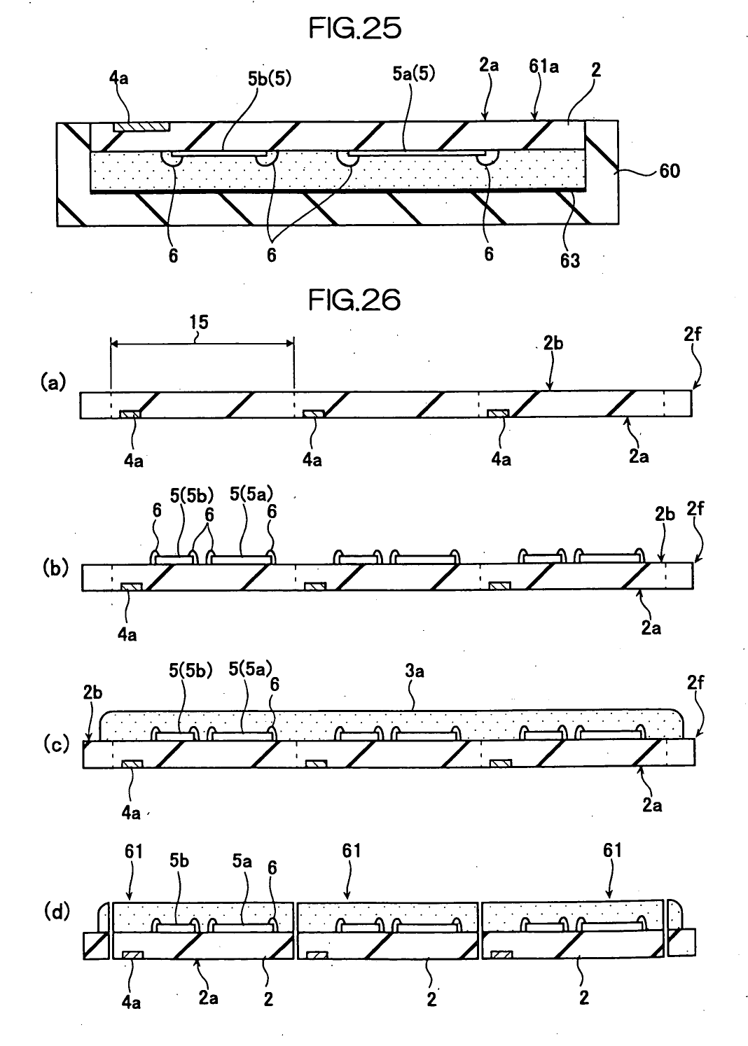

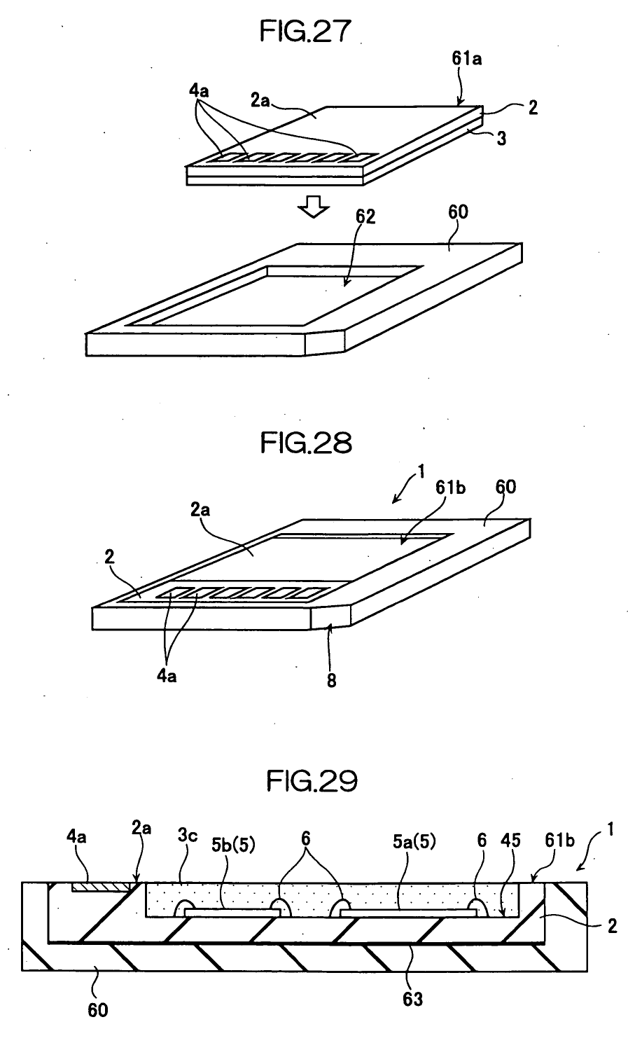

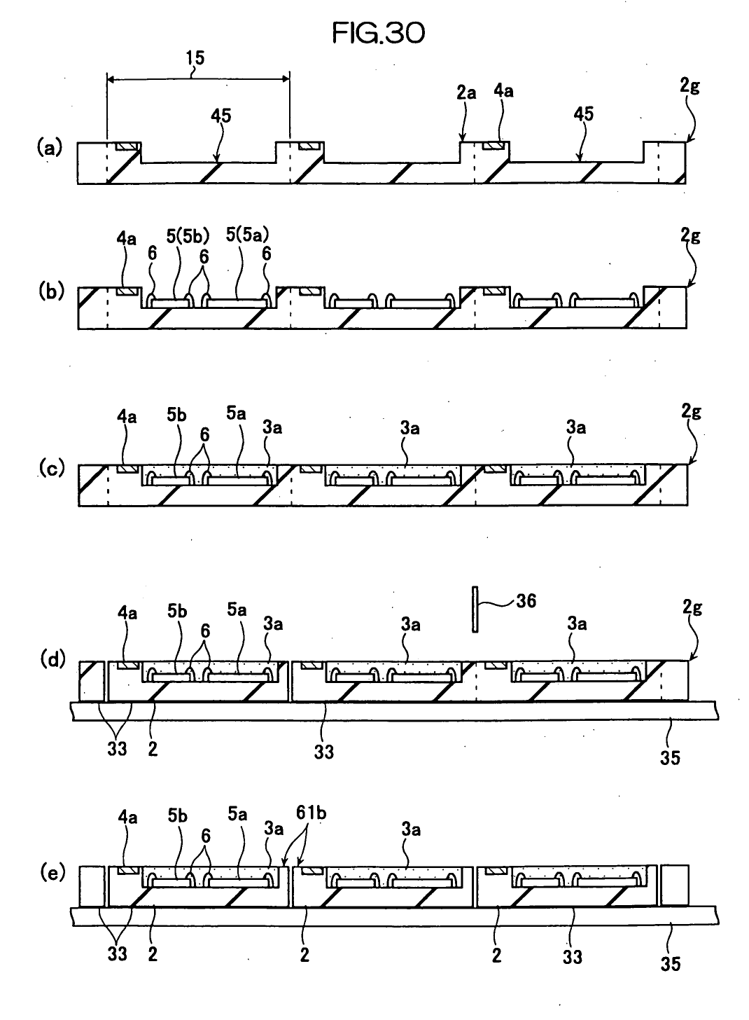

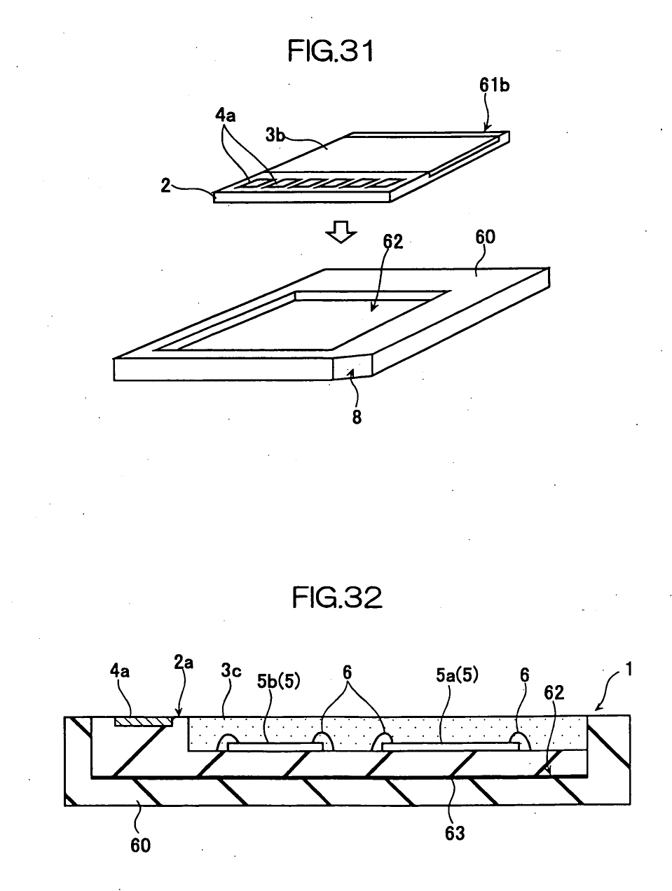

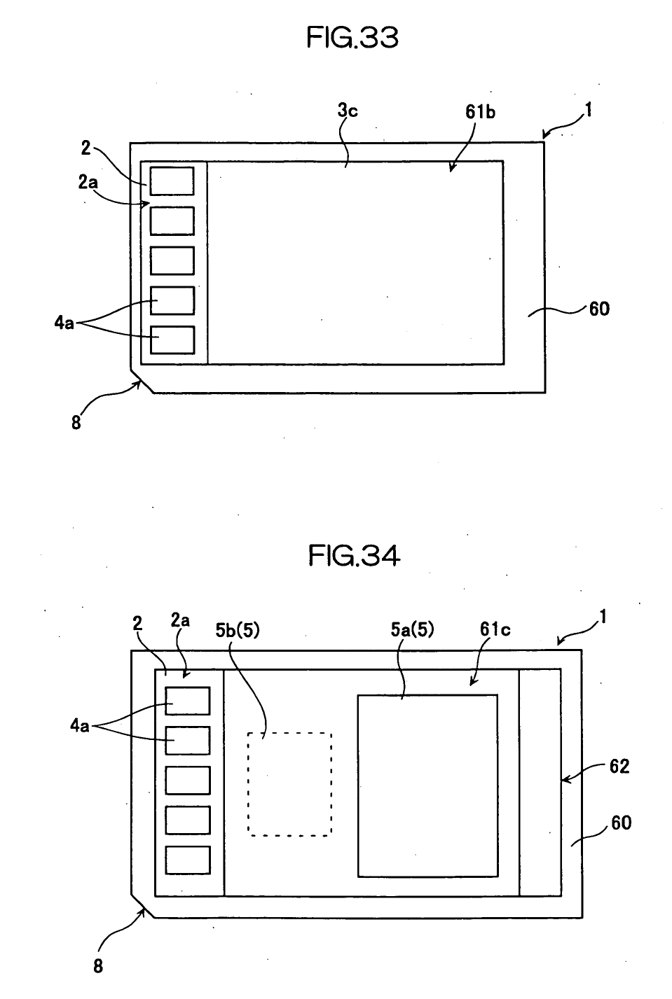

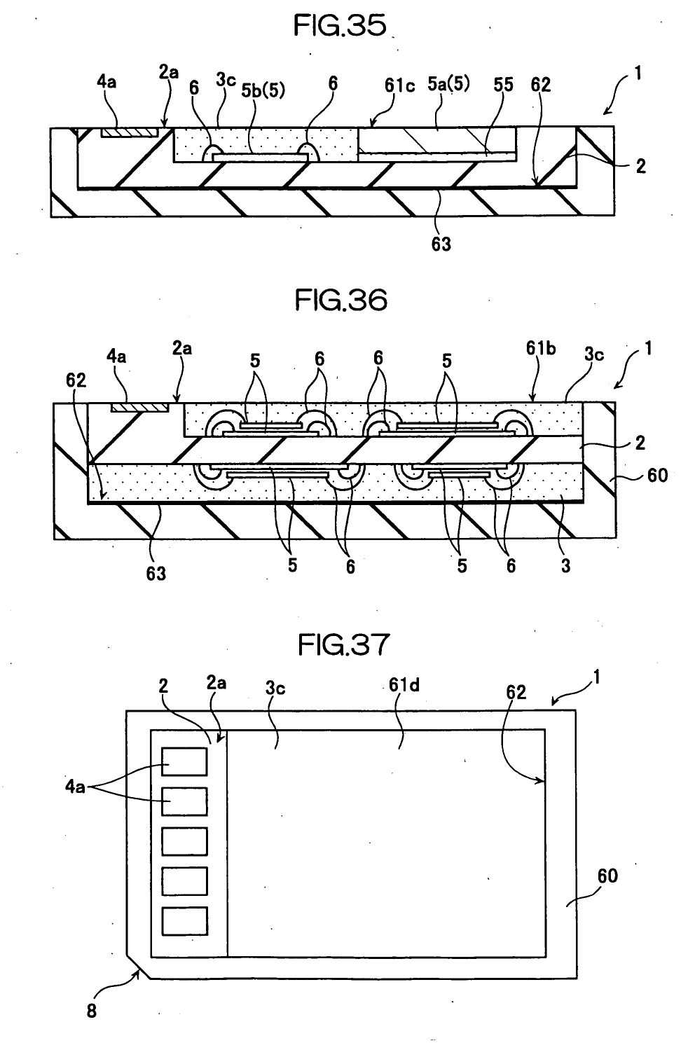

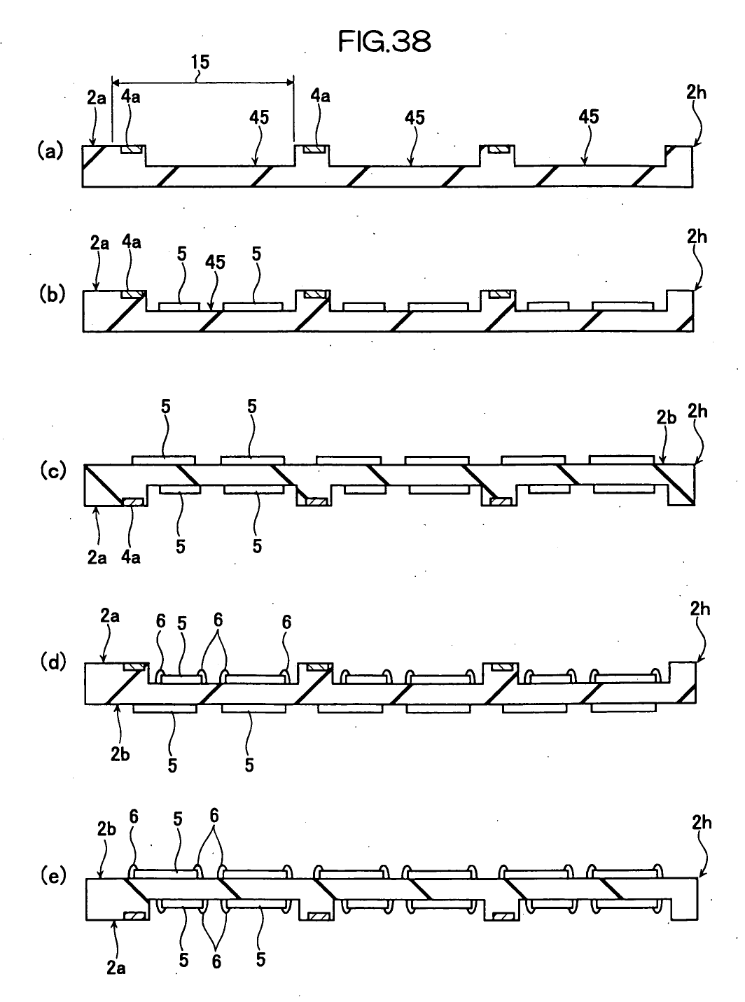

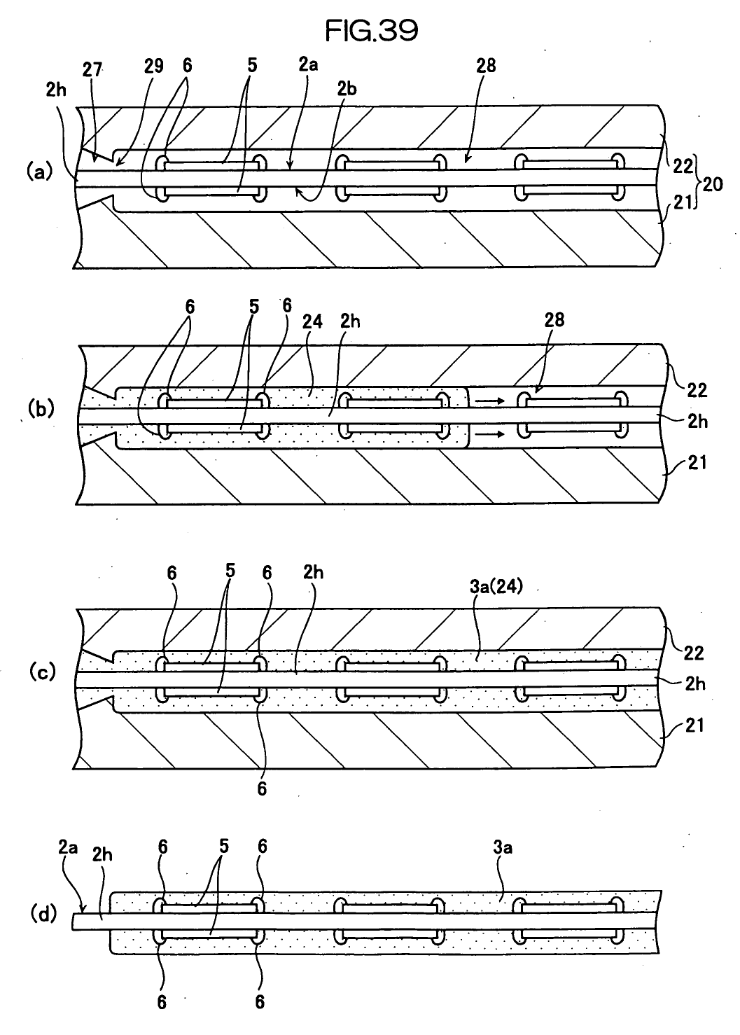

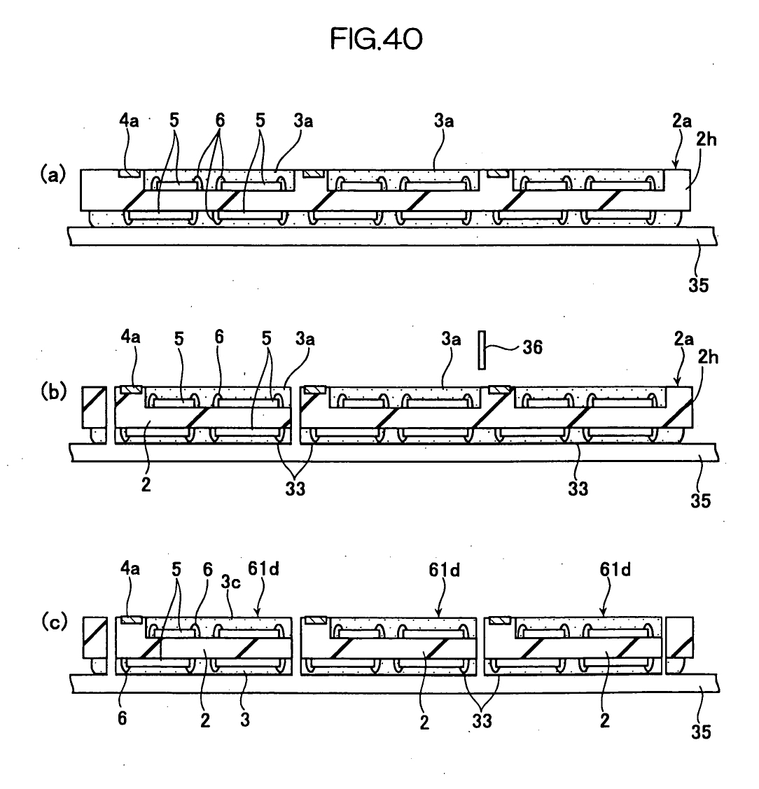

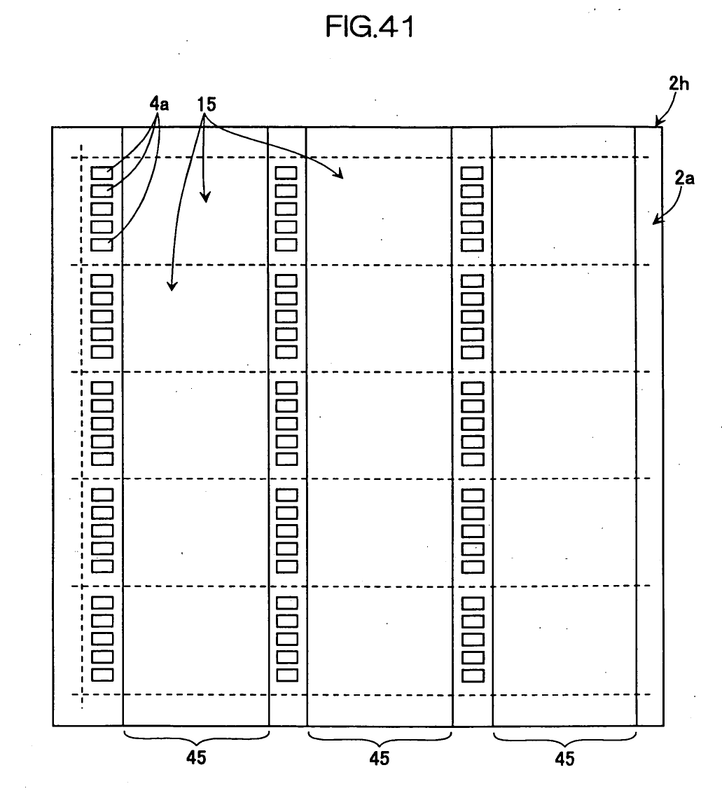

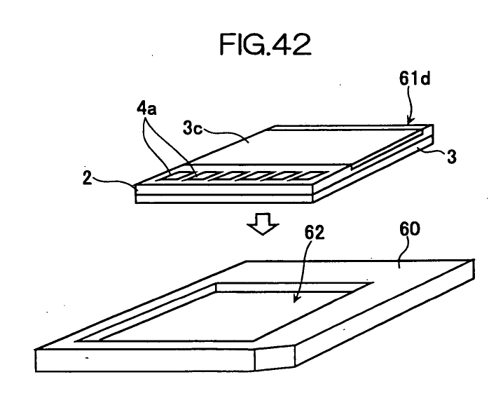

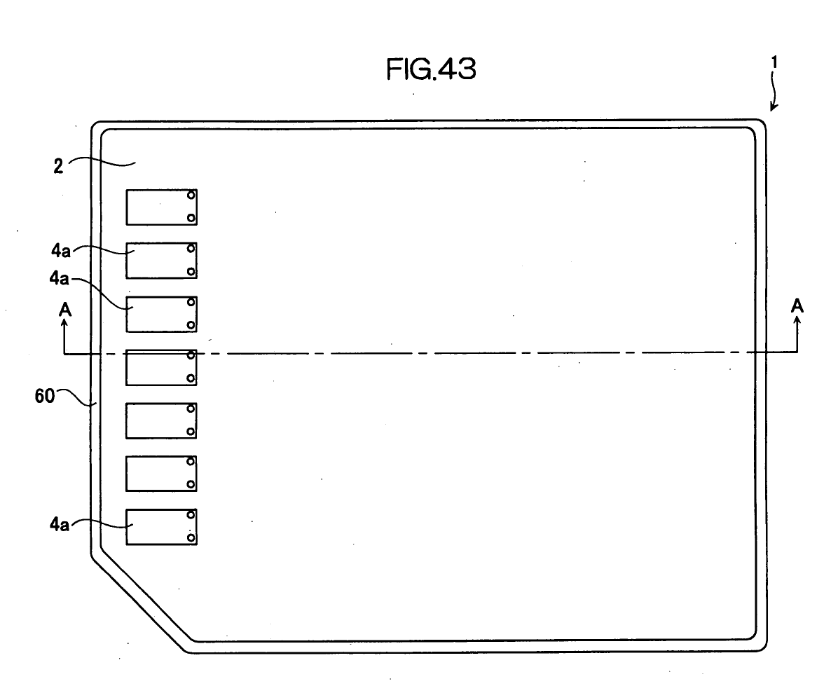

FIGS. 13 to 16 illustrate a memory card according to a further embodiment (third embodiment) of the present invention, of which FIG. 13 is a perspective view of the memory card, showing a state in which the memory card has been turned upside down, and FIG. 14 is a schematic sectional view of the memory card, showing a state in which the memory card has been turned upside down.

In this third embodiment, a wide groove is formed from end to end in a surface or a back surface, i.e., a first or a second surface, of a substrate and semiconductor elements are fixed to the bottom of the groove, further, electrodes on the semiconductor elements and wiring lines are connected together through wires, and the groove is filled up with an insulating resin to the original state. The groove is formed in the direction of arrangement of external electrode terminals which are arranged on the first surface of the substrate. With the insulating resin for filling up the groove, a sealing member is formed by transfer molding in such a manner that the resin flows from one to the opposite end of the groove. Similar to the first embodiment, this is for producing plural memory cards at a time by dividing a single matrix substrate lengthwise and crosswise. Wiring lines connected to wires which are connected at one ends thereof to electrodes on semiconductor elements may be disposed not only on the first or the second surface but also on the bottom of the groove. In the subsequent drawings, wiring lines for wire bonding, etc. may be partially omitted.

In the memory card 1 of this third embodiment, as shown in FIGS. 13 and 14, unlike the memory card 1 of the first embodiment, a sealing member is not provided on a second surface 2b, but a sealing member 3c is provided on a first surface 2a on which external electrode terminals 4a are formed. The sealing member 3c is formed with an insulating resin which is applied in such a manner that a groove 45 formed in the first surface 2a is filled up with the resin to the original state. The groove 45 is formed in the direction of arrangement of the external electrode terminals 4a and throughout the overall length (overall width) of the substrate 2.

The sealing member 3c is formed by transfer molding and is cut simultaneously with cutting of a matrix substrate which will be described later. An upper surface of the sealing member 3c is made flat by a flat surface of a molding die used. Besides, the flat surface of the molding die closes the groove 45 and comes into contact with the first surface 2a located on both sides of the groove 45, so that the flat surface of the sealing member 3c and the first surface 2a become almost flush with each other. Side faces of the sealing member 3c appearing at ends of the groove 45 are formed simultaneously with the matrix substrate when the matrix substrate is cut with a dicing blade, so that the side faces of the sealing member 3c and the associated side faces of the substrate 2 are also flush with each other.

Similar to the first embodiment, within the sealing member 3c, a memory chip 5a and a control chip 5b as semiconductor elements 5 are fixed, and electrodes on the semiconductor elements 5 and wiring lines on the substrate 2 are electrically connected with each other through wires 6.

External dimensions of the memory card 1 of this third embodiment are the same as in the first embodiment, but because of the structure wherein the groove 45 is formed in the first surface 2a of the substrate 2 and semiconductor elements 5 are fixed to the bottom of the groove 45 and are covered with the sealing member 3c, the thickness of the substrate 2 in this third embodiment is larger than that in the first embodiment. However, the overall thickness can be made small because a sealing member is not provided on the second surface 2b of the substrate 2. For example, the thickness of the substrate 2 is as thin as 0.8 mm, and the depth of the substrate is 0.6 mm. Thus, it is possible to attain the reduction in thickness of the memory card 1.

Also in this third embodiment, similar to the second embodiment, there may be adopted a structure in which the semiconductor elements fixing area of the substrate 2 is depressed and semiconductor elements are fixed to the depressed bottom, or a multi-stage mounting structure wherein one or more semiconductor devices are stacked on a semiconductor element, whereby it is possible to attain the same high function, high capacity and reduction of thickness as in the first embodiment. The structures in question may be adopted also in embodiments which will be described as follows.

The memory card 1 of this third embodiment is manufactured by the following method. FIG. 15 is a bottom view of a matrix substrate used in manufacturing the memory card and FIG. 16 is a sectional view showing manufacturing steps for the memory card.

In manufacturing the memory card 1 of this third embodiment there also is used a matrix substrate as in the first embodiment, but this matrix substrate, indicated at 2g, is different in that grooves 45 are formed in the first surface 2a, as shown in FIGS. 15 and 16(a). In the matrix substrate 2g are arranged unit substrate areas 15 in three rows and five columns, but three such grooves 45 as described above are formed so as to cross the unit substrate areas 15 in the direction of arrangement of the external electrode terminals 4a arranged in columns. Therefore, in each unit substrate structure 15, the first surface 2a is present on both sides of the associated groove 45. The thickness of the matrix substrate 2g is 0.8 mm and the depth of each groove 45 is 0.6 mm.

In manufacturing the memory card 1, as shown in FIG. 16(a), the matrix substrate 2g having the grooves 45 is provided and thereafter, as shown in FIG. 16(b), semiconductor elements 5 are fixed to the bottom of the groove in each unit substrate area 15 with use of an adhesive (e.g., silver paste). As the semiconductor elements 5, a memory chip 5a and a control chip 5b for controlling the memory chip 5a are used and fixed.

Next, as shown in FIG. 16(b), electrodes (not shown) on each semiconductor element 5 and wiring lines (wire bonding pads) (not shown) formed on the surface of the matrix substrate 2f are connected together through conductive wires 6.

Next, as shown in FIG. 16(c), only the grooves 45 formed in the first surface 2a of the matrix substrate 2g are filled up with a mold member 3a of an insulating resin by transfer molding. The semiconductor elements and wires 6 are covered with the mold member 3a. The transfer molding is carried out in the same way as in the first embodiment to effect sealing (molding). A parting surface of one of upper and lower molds, e.g., upper mold, becomes a flat surface, which flat surface comes into contact with the first surface 2a of the matrix substrate 2f so as to close the grooves 45. Then, resin is fed from one end sides of the three grooves 45. The resin flows along each groove 45 to close all the groove portions of the five unit substrate areas 15. As a result, the sealing member 3c becomes uniform in thickness (height) and its flat surface and the first surface 2a become nearly flush with each other.

Next, as shown in FIG. 16(d), the matrix substrate 2g is fixed onto a stage 35 of a dicing machine (not shown) using an adhesive 33 and is then cut lengthwise and crosswise with a rotating dicing blade 36. FIG. 16(d) shows a state in which the matrix substrate 2g is cut crosswise (in the width direction of the memory card 1). After the crosswise cutting is over, the stage 35 is turned 90°, followed by lengthwise cutting (in the length direction of the memory card 1), as shown in FIG. 16(e). The cutting is carried out either successively using a single dicing blade or once or several times using plural dicing blades.

Now, a memory card 1 is almost completed in which the sealing member 3c is formed in each of the grooves 45 formed in the first surface 2a of the substrate 2.

Then, one corner of each of the resulting rectangular pieces, i.e., the sealing member portion in which a through holes 16 has been formed in the state of the matrix substrate 2g, is cut along the direction recognizing portion 8 to afford the memory card 1 with the direction recognizing portion (index) 8 shown in FIG. 13. Then, a seal is affixed to the second surface 2b of the substrate 2 of the memory card 2, whereby the memory card 1 becomes employable.

Thus, in this embodiment, a groove 45 is formed in part of the substrate 2 and semiconductor elements are mounted on the bottom of the groove, then the groove is filled with an insulating resin, whereby it is possible to decrease the amount of resin used and attain the reduction in cost of the memory card 1.

In cutting the matrix substrate in this third embodiment, the cutting in the arrangement direction of the external electrode terminals 4a is of only the matrix substrate, so that the cutting performance is improved in comparison with the cutting of both substrate and resin which are mutually different materials, and it is possible to improve the quality and reduce the cutting cost.

### Fourth Embodiment

FIGS. 17 to 21 illustrate a memory card according to a still further embodiment (fourth embodiment) of the present invention, of which FIG. 17 is a sectional view of the memory card which has been turned upside down, FIG. 18 is a bottom view of the memory card, FIG. 19 is a perspective view showing in what state a semiconductor element is mounted in manufacturing the memory card, FIG. 20 is a partial sectional view showing an example of the mounted state of the semiconductor element, and FIG. 21 is a partial sectional view showing another example of a mounted state of the semiconductor element.

In this fourth embodiment, as shown in FIG. 19, the sealing member 3c for filling up the groove 45 in the third embodiment is formed partially and a semiconductor element 5 is fixed by face-down bonding to a groove bottom exposed to a space area 50 in which the sealing member 3c is not formed. For example, as shown in FIG. 20, a surface of the semiconductor element 5 on which surface electrodes 51 of the semiconductor element 5 are formed is set face to face with the groove bottom and the electrodes 51 are connected electrically and mechanically through a bonding material 53 such as solder to bonding pads 52 formed on the groove bottom. Alternatively, as shown in FIG. 21, with an anisotropic conductive adhesive 55 interposed between the groove bottom and the semiconductor element 5, the electrodes 51 on the semiconductor element 5 are fixed electrically and mechanically to the bonding pads 52 formed on the groove bottom.

According to the structure shown in FIG. 20 wherein the electrodes 51 are fixed to the bonding pads 52 through the bonding material 53, an insulating resin (under-fill resin) is filled between the groove bottom and the semiconductor element 5 to form an under-fill portion 54, thereby preventing the entry of water and dust particles between the groove bottom and the semiconductor element 5. According to the structure using the anisotropic conductive adhesive 55, which is shown in FIG. 21, the anisotropic conductive adhesive 55 is compressed between the electrodes 51 on the semiconductor element 5 and the bonding pads 52, whereby conductive particles contained in the anisotropic conductive adhesive 55 contact one another, so that the electrodes 51 and the bonding pads 52 are electrically connected with each other.

FIGS. 17 to 19 illustrate a case where the anisotropic conductive adhesive 55 is used. In this embodiment, though not specially limited, the semiconductor element 5 covered with the sealing member 3c is a control chip 5b and the semiconductor element 5 mounted by face-down bonding is a memory chip 5a.

In this embodiment, the surface portion of the semiconductor element 5 exposed to the outside of the space area 50 is prevented from projecting to the outside from an edge surface of the groove 45, i.e., the first surface 2a. For example, the surface of the semiconductor element 5 is made flush with the surface (first surface 2a) of a substrate 2. This is for preventing the exposed surface of the semiconductor element from being caught in the slot when a memory card 1 is inserted into the slot.

The memory card 1 of this embodiment is fabricated in the following manner. In the manufacturing method using a matrix substrate in the third embodiment, a sealing member 3c is formed in part of the groove 45, while the remaining portion of the groove 45 is not covered with the sealing member 3c, and a semiconductor element 5 is fixed to a part of the groove bottom. For example, the control chip 5b is fixed as the semiconductor element. Thereafter, electrodes on this semiconductor element 5 and wiring lines are electrically connected with each other through wires 6 and then the sealing member 3c is partially connected to the groove bottom so as to cover the semiconductor element 5 and the wires 6.

Next, a semiconductor element 5 is fixed to the groove bottom not covered with the sealing member 3c by face-down bonding. For example, the memory chip 5a is fixed as the semiconductor element. In this connection there may be adopted a method wherein the electrodes 51 on the memory chip 5a and the bonding pads 52 on the groove bottom are connected together using the bonding material 53 shown in FIG. 20, or a method wherein the electrodes 51 on the memory chip 5a and the bonding pads 52 on the groove bottom are electrically connected with each other using the anisotropic conductive adhesive 55, as shown in FIG. 21. According to the method using the bonding material 53, an insulating under-fill resin is poured between the semiconductor element 5 and the groove bottom after the fixing of the semiconductor element, and then the under-fill resin is cured to form an under-fill portion 54.

Next, the matrix substrate is cut lengthwise and crosswise for separation into individual unit substrate areas and one corners of the unit substrate areas are cut off obliquely to form direction recognizing portions 8, whereby such a memory card 1 as shown in FIGS. 17 and 18 is manufactured in a plural number.

Thus, according to this fourth embodiment, since a part of the groove 45 is covered with the sealing member 3c and a semiconductor element 45 is mounted by face-down bonding onto the groove bottom in the space area 50 not covered with the sealing member 3c, it is possible to decrease the inductance of a chip which operates at high speed.

### Fifth Embodiment

FIGS. 22 and 23 illustrate a memory card according to a still further embodiment (fourth embodiment) of the present invention, of which FIG. 22 is a sectional view of the memory card which has been turned upside down and FIG. 23 is a bottom view of the memory card.

As shown in FIG. 22, the memory card, indicated at 1, of this fifth embodiment is of a structure wherein semiconductor elements 5 are mounted on each of a surface and a back surface, i.e., a first surface 2a and a second surface 2b, of a substrate 2 and are covered with sealing members 3c and 3. According to the illustrated structure, moreover, onto semiconductor elements 5 are fixed semiconductor elements 5 smaller in size than the former semiconductor elements on both first and second surfaces 2a, 2b, and electrodes and wiring lines (neither shown) are electrically connected with each other through wires 6. That is, the structure of this third embodiment is a combined structure of both first and third embodiments.

In manufacturing the memory card 1 of this fifth embodiment there is used a matrix substrate 2g having grooves 45 as shown in FIG. 15 which is related to the third embodiment. However, since semiconductor elements 5 are stacked in two stages on the groove bottom, the depth of each groove 45 is large and the thickness of the matrix substrate 2g becomes so much larger.

In such a matrix substrate (not shown), first a predetermined number of semiconductor elements 5 are fixed to the groove bottom of each unit substrate area. Likewise, a predetermined number of semiconductor elements 5 are fixed also to the second surface 2b of the substrate in each unit substrate area. In this example, after semiconductor elements 5 have been fixed to the matrix substrate, semiconductor elements 5 of a smaller size are stackedly fixed onto the former semiconductor elements in such a manner that electrodes on the underlying semiconductor elements 5 are exposed.

Next, electrodes on each semiconductor element and wiring lines are electrically connected with each other through wires 6.

Then, the grooves 45 are filled up with an insulating resin to form a mold member which covers the semiconductor elements 5 and the wires 6. Also, the insulating resin is applied to the whole of the second surface 2b so as to cover the semiconductor elements 5 and wires 6 on the second surface 2b to form a mold member. Both mold members are formed simultaneously by transfer molding using a molding die.

Next, the matrix substrate is cut lengthwise and crosswise for separation into individual unit substrate areas, and one corner of each unit substrate area is cut obliquely to form a direction recognizing portion 8. In this way such a memory card 1 as shown in FIGS. 23 and 22 is fabricated in a plural number.

According to the structure of this fifth embodiment, since semiconductor elements are mounted on both surface and back surface of the substrate 2, it is possible to attain high function and high capacity of the memory card 1. In this fifth embodiment, moreover, since semiconductor elements 5 are fixed in plural stages onto semiconductor elements 5, it is possible to attain still higher function and larger capacity.

### Sixth Embodiment

In memory cards according to sixth to ninth embodiments of the present invention, in manufacturing the memory cards of the first and third to fifth embodiments, the matrix substrate is cut lengthwise and crosswise, and COB package before the cutting to form a direction recognizing portion is fitted in a plastic case and fixed thereto by bonding. External electrode terminals provided on one surface of a substrate which constitutes the COB package are accommodated in an exposed state into the case and are used as external electrode terminals of a memory card obtained. An obliquely extending direction recognizing portion is formed at one corner of the plastic case which is rectangular in shape. It goes without saying that the direction recognizing portion may be of another shape (structure).

FIGS. 24 to 27 illustrate a memory card according to a still further embodiment (sixth embodiment) of the present invention, of which FIG. 24 is a perspective view of the memory card which has been turned upside down, FIG. 25 is a sectional view of the memory card which has been turned upside down, FIG. 26 is a sectional view showing memory card manufacturing steps, and FIG. 27 is a perspective view showing in what state a COB package is mounted to a case in manufacturing the memory card.

According to the structure of the memory card, indicated at 1, of this sixth embodiment, as shown in FIG. 27, a COB package 61a is fitted in a recess 62 of a case 60 which is formed of a plastic material, and as shown in FIG. 25, the COB package 61a is bonded using an adhesive 63. In the memory card 1, the COB package 61a is received in the case 60 in an exposed state external electrode terminals 4a formed on one surface of a substrate 2 which constitutes the COB package 61a. The external electrode terminals 4a are used as external electrode terminals of the memory card 1 (see FIG. 24).

Thus, the memory card 1 of this sixth embodiment has a structure in which the COB package product formed in the first embodiment is accommodated in a plastic case. In the first embodiment a matrix substrate after molding is cut lengthwise and crosswise, followed by cutting to form direction recognizing portions, thereby fabricating memory cards 1. But in this sixth embodiment, a matrix substrate is cut lengthwise and crosswise to form quadrangular COB packages, then each of the COB packages is fitted in the case 60 and is bonded thereto to afford the memory card 1. At a corner of the case 60 there is formed an obliquely cut direction recognizing portion 8.

The case 60 is formed of resin (e.g., PPE: poly phenyl ether) and has a simple structure having in one surface thereof a recess 62 for fitting therein of the COB package 61a. Therefore, the molding cost is inexpensive.

External dimensions of the case 60 are, for example, 32 mm long, 24 mm wide, and 1.4 mm thick. The COB package 61a has external dimensions of 28 mm long, 19 mm wide, and 0.8 mm thick so as to permit fitting thereof into the recess 62 of the case 60. A bottom thickness of the recess of the case 60 is 0.5 mm and the thickness of the substrate 2 which constitutes the COB package 61a is 0.21 mm.

Now, with reference to FIGS. 26(a) to 26(d), a description will be given below about in what manner the COB package 61a is fabricated. The description will be brief because many of manufacturing steps adopted here are the same as in the first embodiment. FIGS. 26(a) to 26(d) are sectional views showing COB package manufacturing steps, of which FIG. 26(a) is a matrix substrate providing step, FIG. 26(b) is a chip bonding and wiring bonding step, FIG. 26(c) is a molding step, and FIG. 26(d) is a matrix substrate separating step.

As shown in FIG. 26(a), also in manufacturing the memory card 1 of this sixth embodiment there is used the same matrix substrate 2f as that used in the first embodiment. However, the size of each unit substrate area in the matrix substrate of this sixth embodiment is smaller than in the first embodiment because the COB package is fitted in the case 60. For example, the size of each unit substrate area 15 is 28 mm long, 19 mm wide, and 0.21 mm thick.

Next, as shown in FIG. 26(b), chip bonding is performed for a second surface 2b of the matrix substrate 2f, and a memory chip 5a and a control chip 5b are fixed as semiconductor elements.

Then, as shown in FIG. 26(b), electrodes on each semiconductor element 5 and wiring lines (wire bonding pads) on a surface of the matrix substrate 2f are connected together using conductive wires 6.

Next, as shown in FIG. 26(c), a mold member 3a of a predetermined certain thickness is formed on the second surface 2b of the matrix substrate 2f by a conventional transfer molding technique.

Then, as shown in FIG. 26(d), the matrix substrate 2f is diced by means of a dicing machine (not shown) to form COB packages 61a each including a unit substrate area 15.

Next, as shown in FIG. 27, each of the COB packages 61a is fitted in the case 60 in an exposed state of external electrode terminals 4a and is fixed to the case using an adhesive to fabricate such a memory card 1 as shown in FIGS. 24 and 25.

In the COB package of such a conventional structure as shown in FIGS. 43 and 44, when forming the sealing member 3, it is possible that the volume of a clearance between the plastic case 60 and the COB package will change due to a change in volume with curing of the sealing resin. Such a change in the clearance between the case 60 and the COB package can cause a poor adhesion between the two. In order to ensure a satisfactory adhesion between the case 60 and the COB package, if the clearance between the two is taken large and the amount of the adhesion to be fed is set so much larger in advance, there may occur protrusion of the adhesive.

On the other hand, in manufacturing the memory card 1 of this sixth embodiment, since dicing is performed after a curing reaction of a sealing resin 24, a planar size of the wiring substrate 2 is not influenced by a change in volume caused by a curing reaction of the sealing resin 24, thus permitting improvement of the dimensional accuracy. Consequently, the clearance between the recess 62 in the case 60 and the COB package 61a can be diminished particularly in the planar direction. Besides, by thus narrowing the clearance between side faces of the COB package 61a and side faces of the recess 62, it is possible prevent protrusion of the adhesive even in case of bonding the COB package 61a and the case 60 with each other through a pasty adhesive of low cost.

In the COB package of such a conventional structure as shown in FIGS. 43 and 44, when a sealing member is to be formed by individual sealing in accordance with a transfer molding method, a resin pouring gate, a runner as a resin pouring path, or an air vent of a mold cavity is disposed on a wiring substrate in each device area and around the sealing member, so that unnecessary resin burrs may remain on that portion. Such burrs can contribute to a poor adhesion between the case and the COB package and floating or tilting of the substrate. For the purpose of preventing the occurrence of a defect caused by such burrs, if a sufficient clearance is set between the case and the COB package and if the amount of the adhesive to be fed is set so much larger, there can occur protrusion of the adhesive.

In the memory card 1 of this sixth embodiment, such portions as gate 29, runner 27, and air vent 30 are arranged outside the portion which serves as the COB package 61a and are subjected to dicing, so it is possible to prevent the occurrence of resin burrs and hence possible to set narrow the clearance between the case 60 and the COB package.

In the COB package of such a conventional structure as shown in FIGS. 43 and 44, in case of adopting individual sealing by a potting method in the sealing member forming step, there occur variations in the shape of the sealing member which is attributable to the potting method. Such variations in shape can cause a poor adhesion between a cap and the COB package. In order to ensure the adhesion between the cap and COB package, if the amount of the adhesive to be fed is set so much larger in advance, there can occur protrusion of the adhesive.

On the other hand, in the memory card 1 of this sixth embodiment, even if there is adopted a potting method in which it is difficult to control the shape of the peripheral edge portion of the mold member 3a, it is possible to diminish shape variations and effect a satisfactory adhesion between the case 60 and the COB package 61a.

In the COB package of such a conventional structure as shown in FIGS. 43 and 44, the thin substrate portion which spreads around the sealing member is low in strength and is very likely to be peeled off when the memory card is in use. To prevent such peeling, bonding of the substrate portion has heretofore been necessary. However, it is difficult to feed an adhesive or an adhesive tape up to the peripheral edge portion of the recess formed in the case having concave and convex. It has also been difficult to prevent wetting and spreading of a pasty adhesive.

On the other hand, in the memory card 1 of this sixth embodiment, since the sealing member 3 is formed also on the peripheral edge portion of the second surface 2b of the substrate 2 which constitutes the COB package 61a, the strength of the peripheral edge portion of the COB package 61a is high and hence it is possible to prevent peeling during use of the memory card 1.

Moreover, in the memory card 1 of this sixth embodiment, since there is neither a large concave nor a large convex at the bottom of the recess 62 of the case 60, the supply of an adhesive or an adhesive tape is easy and it becomes easy to control wetting and spreading of a pasty adhesive.

Further, in the memory card 1 of this sixth embodiment, since the occurrence of peeling during use of the memory card is less possible, it is possible to adopt a structure in which only a central portion of the COB package 61a is bonded to the case 60 through a pasty adhesive or an adhesive tape, while the peripheral edge or side wall portion of the COB package 61a is not bonded to the case 60. Particularly, in case of using a pasty adhesive for the bonding with the case 60, the likelihood of adhesive leakage can be further diminished by failure to bond the peripheral edge or side wall portion of the COB package 61a.

### Seventh Embodiment

FIGS. 28 to 31 illustrate a memory card according to a still further embodiment (seventh embodiment) of the present invention, of which FIG. 28 is a perspective view of the memory card which has been turned upside down, FIG. 29 is a sectional view of the memory card which has been turned upside down, FIG. 30 is a sectional view showing memory card manufacturing steps, and FIG. 31 is a perspective view showing in what state a COB package is mounted to a case in manufacturing the memory card.

According to the structure of the memory card 1 of this seventh embodiment, as shown in FIG. 31, a COB package 61b is fitted in a recess 62 formed in a plastic case 60, and as shown in FIG. 29, the COB package 61b is bonded to the case with an adhesive 63. In the memory card 1, the COB package 61b is received in the case 60 in an exposed state of external electrode terminals 4a formed on one surface of a substrate 2 which constitute the COB package 61b. The external electrode terminals 4a are used as external electrode terminals of the memory card 1 (see FIG. 28).

Thus, the memory card 1 of this seventh embodiment is of a structure in which the COB package formed in the third embodiment is accommodated in a plastic case. In the third embodiment the matrix substrate is cut lengthwise and crosswise after molding, followed by cutting to form direction recognizing portions, while in this seventh embodiment, a matrix substrate is cut lengthwise and crosswise to form quadrangular COB packages and thereafter each of the COB packages is fitted and bonded to the same case 60 as in the sixth embodiment to fabricate the memory card 1.

Therefore, also in this seventh embodiment there is obtained a part of the effect obtained in the third embodiment; besides, as in the sixth embodiment, since the sealing member 3 in the COB package 61b is received in the case, the memory card 1 is strong and less expensive.

Next, with reference to FIGS. 30(a) to 30(e), a brief description will be given below about in what manner the COB package 61b is fabricated. FIGS. 30(a) to 30(e) are sectional views showing COB package manufacturing steps, of which FIG. 30(a) is a matrix substrate providing step, FIG. 30(b) is a chip bonding and wire bonding step, FIG. 30(c) is a molding step, and FIGS. 30(d) and 30(e) are a matrix substrate separating step.

As shown in FIG. 30(a), also in manufacturing the memory card 1 of this seventh embodiment, there is used a matrix substrate 2g having grooves 45 as in the third embodiment. However, because of the structure wherein the COB package is fitted in the case 60, the size of each unit substrate area 15 in the matrix substrate of this seventh embodiment is smaller than in the first embodiment. For example, it is 28 mm long, 19 mm wide, and 0.8 mm thick.

Next, as shown in FIG. 30(b), chip bonding is performed for bottoms of the grooves 45 formed in a first surface 2a of the matrix substrate 2g and memory chips 5a and control chips 5b are fixed as semiconductor elements 5.

Then, as shown in FIG. 30(b), electrodes on the semiconductor elements 5 and wiring lines (not shown) formed on a surface of the matrix substrate 2g are connected with each other using conductive wires 6.

Next, as shown in FIG. 30(c), a mold member 3a is formed by the same transfer molding method as in the third embodiment so as to close the grooves 45 formed in the first surface 2a of the matrix substrate 2g.

Then, as shown in FIG. 30(d), the matrix substrate 2g is fixed onto a stage 35 of a dicing machine (not shown) though an adhesive 33 and is diced with a dicing blade 36 to form COB packages 61b each including a unit substrate area 15 (see FIG. 30(e)).

Next, as shown in FIG. 31, each COB package 61b is fitted in the recess 62 of the case 60 in an exposed state of external electrode terminals 4a and is fixed thereto through an adhesive 63 (see FIG. 29) to fabricate such a memory card 1 as shown in FIGS. 28 and 29.

The memory card 1 of this seventh embodiment not only possesses a part of the effects which the memory card of the third embodiment possesses, but also is strong because one surface and peripheral edge of the COB package 61b are covered with the case 60 and are protected thereby.

FIG. 32 is a sectional view of a memory card according to a modification of the seventh embodiment of the present invention, showing a state in which the memory card has been turned upside down, and FIG. 33 is a bottom view of the memory card. According to this modification, three grooves 45 are formed in the state of a matrix substrate and memory cards 1 are fabricated. But the grooves 45 extend up to one ends of unit substrate areas 15. Therefore, in the state illustrated in FIGS. 32 and 33, an end of the sealing member 3c extends up to an inner periphery edge of the case 60.

According to this modification, since the width of each groove 45 is large, it is possible to mount semiconductor elements of larger sizes and hence possible to attain high function and high capacity.

### Eighth Embodiment

FIG. 34 is a bottom view showing a back surface of a memory card according to a still further embodiment (eighth embodiment) of the present invention and FIG. 35 is a sectional view of the memory card which has been turned upside down.

The memory card 1 of this eighth embodiment is of a structure in which a COB package 61c is fitted and bonded to a recess 62 formed in a case 60. According to the COB package 61c, in the COB package 61b of the seventh embodiment, a sealing member 3c is partially formed in a groove 45 and a semiconductor element 5 is mounted by face-down bonding in an area where the sealing member 3c is not formed. This sealing form is based on the structure of the fourth embodiment.

For mounting the semiconductor element 5 by face-down bonding there may be adopted a method wherein electrodes on the semiconductor element 5 and bonding pads 52 on the substrate 2 are electrically connected with each other using the bonding material 53 used in the fourth embodiment and shown in FIG. 20 or a method in which electrodes 51 on the semiconductor element 5 and bonding pads 52 on the substrate 2 are electrically connected with each other using the anisotropic conductive adhesive 55 shown in FIG. 21. The memory card shown in FIGS. 34 and 35 is fabricated using the anisotropic conductive adhesive 55.

Not only the memory card 1 of this eighth embodiment possesses a part of the effects obtained in the seventh and fourth embodiments but also is strong because one surface and peripheral edge of the COB package 61c are covered with the case 60.

### Ninth Embodiment

FIGS. 36 to 42 illustrate a memory card according to a still further embodiment (ninth embodiment) of the present invention and also illustrate a method of manufacturing the memory card.

In the memory card 1 of this ninth embodiment, as shown in FIG. 42, a COB package 61d is fitted in a recess 62 formed in a plastic case 60, and as shown in FIG. 36, the COB package 61d is bonded using an adhesive 63. The memory card 1 is of a structure in which the COB package 61d is accommodated in the case 60 in an exposed state of external electrode terminals 4a formed on one surface of a substrate 2 which constitutes the COB package 61d. The external electrode terminals 4a are used as external electrode terminals of the memory card 1 (see FIG. 37).

More specifically, in the memory card 1 of this ninth embodiment, the COD package 61d is received in a plastic case, the COD package 61d comprising a substrate 2 and semiconductor elements 5 mounted on both surface and back surface of the substrate and covered with sealing members 3 and 3c as in the fifth embodiment. In the COB package 61d, as in the modification of the seventh embodiment, an end of the sealing member 3c extends up to an inner periphery edge of the case 60, whereby semiconductor elements of larger sizes can be mounted.

According to the structure of this ninth embodiment, semiconductor elements 5 are mounted on both surface and back surface of the substrate 2, semiconductor elements 5 are mounted in multiple stages, and the width of each groove 45 is made large to permit mounting of larger-sized semiconductor elements 5, whereby there can be attained high function and high capacity of the memory card 1.

Besides, the COB package 61d is received and fixed to the recess 62 formed in the case 60 and one surface and peripheral edge of the COB package 61d are protected by the case 60, so that the memory card 1 becomes stronger.

Next, with reference to FIGS. 38 to 40 and 41, a brief description will be given below about in what manner the COB package 61d is fabricated. FIGS. 38(a) to 38(e) are sectional views showing states of chip bonding to wire bonding steps in manufacturing the COB package. FIGS. 39(a) to 39(d) are sectional views showing states of transfer molding steps in manufacturing the COB package. FIGS. 40(a) to 40(c) are sectional views showing states of matrix substrate dicing steps in manufacturing the COB package.

In manufacturing the memory card 1 of this ninth embodiment there is used such a matrix substrate 2h as shown in FIGS. 41 and 38(a). Similar to the third embodiment, the matrix substrate 2h has grooves 45. However, the grooves 45 formed in the matrix substrate 2h are so wide as to reach ends of adjacent unit substrate areas 15, and in a diced state of the matrix substrate 2h, one groove ends serve as cutting allowances and vanish into such a state as shown in FIG. 32 of the seventh embodiment. Thus, the area which permits the mounting of semiconductor elements 5 is expanded.

Next, as shown in FIG. 38(b), chip bonding is performed for the bottoms of grooves 45 formed in a first surface.2a of the matrix substrate 2h.

Then, as shown in FIG. 38(c), the matrix substrate 2h is turned upside down and chip bonding is performed for a flat, second surface 2b of the matrix substrate. As the semiconductor elements 5 fixed to both surface and back surface of the matrix substrate 2h there are used plural memory chips and control chips for controlling the memory chips in order to fulfill predetermined functions of the memory chip 1.

Then, as shown in FIG. 38(d), the matrix substrate 2h is turned upside down, and electrodes on the semiconductor elements 5 fixed to the bottom of the groove and wiring lines (not shown) formed on the surface of the matrix substrate 2h are connected together using conductive wires 6.

Then, as shown in FIG. 38(e), the matrix substrate 2h is turned upside down, and electrodes on the semiconductor elements 5 fixed to the flat second surface 2b and wiring lines (not shown) formed on the surface of the matrix substrate 2h are connected together using conductive wires 6.

Next, as shown in FIG. 39(a), the matrix substrate 2h which has been subjected to wire bonding is clamped between a lower mold 21 and an upper mold 22 of a molding die 20 in a transfer molding machine. FIG. 39 is a sectional view taken along the extending direction of the grooves 45.

By the clamping performed with both lower mold 21 and upper mold 22 there are formed cavities 28 on both surface and back surface sides of the matrix substrate 2h. As in FIG. 9, runners 27 are connected to the cavities 28. Gates 29 are formed at boundary portions between the runners 27 and the cavities 28. Air vents (not shown) are positioned at ends of the cavities 28 located on the side opposite to the gates 29.

As shown in FIG. 39(b), by an injecting operation of a plunger (not shown), resin 24 flowing through the runners 27 passes through the gates 29 and flows into the cavities 28. When the cavities 28 are wholly filled with the resin 24, the resin 24 is cured to form a mold member 3a, as shown in FIG. 39(c).

Next, as shown in FIG. 39(d), the matrix substrate 2h now provided with the mold member 3a is taken out from the molding die.

Then, as shown in FIG. 40(a), the matrix substrate 2h having been subjected to molding is fixed onto a stage 35 of a dicing machine (not shown) with use of an adhesive 33. Further, as shown in FIGS. 40(b) and 40(c), the matrix substrate 2h is diced with a dicing blade 36 to form COB packages 61d each including a unit substrate area 15 (see FIG. 42).

Next, as shown in FIG. 42, each COB package 1d is fitted in the recess 62 of the case 60 in an exposed state of external electrode terminals 4a and is fixed thereto through an adhesive 63 (see FIG. 36) to fabricate such a memory card 1 as shown in FIGS. 36 and 37.

The memory card 1 of this ninth embodiment not only possesses a part of the effects which the memory card of the fifth embodiment possesses, but also is strong because one surface and peripheral edge of the COB package 61d are covered with the case 60.

Although the present invention has been described above concretely by way of embodiments thereof, it goes without saying that the present invention is not limited to the above embodiments, but that various changes may be made within the scope not departing from the gist of the invention.

Although the present invention has been described above mainly about the case where the invention is applied to the manufacture of a memory card as a background application field thereof, no limitation is made thereto.

The present invention is applicable at least to an electronic device of a COB package structure.

The following is a brief description of effects obtained by typical modes of the present invention as disclosed herein.

(1) It is possible to provide an electronic device of an inexpensive package structure.

(2) It is possible to provide an electronic device of an inexpensive package structure which permits the attainment of high function and large capacity.

(3) It is possible to provide an inexpensive memory card which permits the attainment of high function and large capacity.

The various modes of the present invention described above are not limited to the construction which solves all of the problems described herein, but include constructions which each solve only one or plural specific problems.

### INDUSTRIAL APPLICABILITY

As set forth above, the memory card as an electronic device according to the present invention is employable as a storage medium having high function and large capacity and being inexpensive in, for example, a digital camera or an audio player. Besides, the memory card manufacturing method according to the present invention permits reduction in the number of manufacturing steps as compared with the number of manufacturing steps for this type of products so far adopted. Consequently, the memory card manufacturing cost can be further decreased.

What is claimed is:

1. A memory card having a first surface and a second surface as a back surface of the first surface, the memory card comprising:
a wiring substrate having a main surface and a back surface;
a plurality of external electrode terminals formed on the back surface of the wiring substrate;
a plurality of wiring lines formed over the main surface of the wiring substrate;
a semiconductor element disposed over the main surface of the wiring substrate and connected electrically to the plural external electrode terminals through a plurality of wiring lines; and
a sealing member formed of an insulating resin on the back surface of the wiring substrate to cover the semiconductor element,
wherein the external electrode terminals and the back surface of the wiring substrate are exposed to the first surface of the memory card, and
wherein the sealing member is exposed to the second surface of the memory card.

2. A memory card according to claim 1, wherein the sealing member covers the plural wiring lines from above.

3. A memory card according to claim 1, wherein the semiconductor element comprises a control chip and a memory chip.

4. A memory card according to claim 1, wherein the semiconductor element comprises a first semiconductor chip disposed over the main surface of the wiring substrate and a second semiconductor chip disposed on the first semiconductor chip.

5. A memory card according to claim 4, wherein over the main surface of the wiring substrate, a semiconductor element fixing area for fixing therein of the semiconductor element is recessed and the semiconductor element is fixed to a bottom of the recess.

6. A memory card according to claim 1, wherein a direction recognizing portion is formed at edges of the wiring substrate and the sealing member.

7. A memory card comprising:
a wiring substrate having a main surface and a back surface;
a plurality of external electrode terminals formed on the back surface of the wiring substrate;
a plurality of wiring lines formed over the main surface of the wiring substrate;
a semiconductor element disposed over the main surface of the wiring substrate and connected electrically to the plural external electrode terminals through the plural wiring lines; and
a sealing member formed of an insulating resin on the back surface of the wiring substrate to cover the semiconductor element,
wherein an interface where the wiring substrate and the sealing member are bonded together is exposed to a side face of the memory card.

8. A method of manufacturing an electronic device, comprising the steps of:
(a) providing a wiring substrate, the wiring substrate having unit substrate areas over a main surface thereof and a plurality of external electrode terminals on a back surface thereof;
(b) arranging semiconductor chips on the unit substrate areas and connecting the semiconductor chips electrically to the plural external electrode terminals;
(c) forming a sealing member for sealing the semiconductor chips over the unit substrate areas and also over the main surface portion of the wiring substrate located around the unit substrate areas;
(d) cutting the sealing member and the wiring substrate simultaneously at positions between the unit substrate areas and the surrounding portions to afford individual pieces, the individual pieces each comprising the wiring substrate of the unit substrate area, the sealing member on the unit substrate area, the semiconductor chip on the unit substrate area, and the plural external electrode terminals;
(e) providing a case having a recess; and
(f) bonding the sealing member to a bottom of the recess and fixing each of the individual pieces to the interior of the recess.

9. A method according to claim 8, wherein the cutting of the step (d) is carried out by dicing.

10. A method according to claim 8, wherein the case provided in the step (e) is formed with a direction recognizing portion.

11. A method according to claim 8, wherein the step (f) comprises the steps of: feeding a pasty adhesive to the bottom of the recess; disposing the individual piece in the interior of the recess; and curing the adhesive to bond the sealing portion of the individual piece and the bottom of the recess to each other through the adhesive.

12. A method according to claim 8, wherein the semiconductor chips arranged in the step (b) each comprise a memory chip and a control chip, and the electronic device formed by the manufacturing steps is a memory card.

13. A method of manufacturing an electronic device, comprising the steps of:
(a) providing a wiring substrate, the wiring substrate having first and second unit substrate areas over a main surface thereof, also having a plurality of first external electrode terminals on a back surface of the first unit substrate area, and further having a plurality of second external electrode terminals on a back surface of the second unit substrate area;
(b) disposing a first semiconductor chip in the first unit substrate area, connecting the first semiconductor chip electrically to the plural first external electrode terminals, disposing a second semiconductor chip in the second unit substrate area, and connecting the second semiconductor chip electrically to the plural second external electrode terminals;
(c) forming over the first and second unit substrate areas a sealing member for sealing the first and second semiconductor chips;
(d) cutting the sealing member and the wiring substrate simultaneously at a position between the first and second unit substrate areas to form a first individual piece and a second individual piece, the first individual piece comprising the wiring substrate located in the first unit substrate area, a first sealing portion formed over the first unit substrate area, the first semiconductor chip, and the first plural external electrode terminals, the second individual piece comprising the wiring substrate located in the second unit substrate area, a second sealing portion formed over the second unit substrate area, the second semiconductor chip, and the plural second external electrode terminals;
(e) providing a first case having a recess; and
(f) bonding the first sealing portion to a bottom of the recess in the first case and fixing the first individual piece to the interior of the recess in the first case.

14. A method according to claim 13, further comprising the steps of:
(g) providing a second case having a recess; and
(h) bonding the second sealing portion to a bottom of the second case and fixing the second individual piece to the interior of the recess in the second case.

15. A method according to claim 13, wherein the cutting of the step (d) is carried out by dicing.

16. A method according to claim 13, wherein the first case provided in the step (e) is formed with a direction recognizing portion.

17. A method according to claim 13, wherein the step (f) comprises the steps of: feeding a pasty adhesive to the bottom of the recess in the first case; disposing the first individual piece in the interior of the recess through the pasty adhesive; and curing the adhesive to bond the first sealing portion and the bottom of the recess to each other through the adhesive.

18. A method according to claim 13, wherein the first and second semiconductor chips arranged in the step (b) each comprise a memory chip and a control chip, and the electronic device formed by the manufacturing steps is a memory card.

19. An electronic device comprising:
a substrate having wiring lines with a plurality of external electrode terminals exposed to a first surface of the substrate;
a groove formed in a second surface as a back surface opposite to the first surface of the substrate or in the first surface in the direction of arrangement of the external electrode terminals and throughout the overall length of the substrate;
a sealing member formed of an insulating resin, the sealing member being buried in the groove to fill up the groove; and
at least one semiconductor element covered with the sealing member, fixed to a bottom of the groove, and having electrodes connected electrically to the wiring lines through a connecting means.

20. An electronic device according to claim 19, wherein the sealing member has a flat surface, the flat surface being substantially flush with substrate surface portions located on both sides of the groove.

21. An electronic device according to claim 19, wherein the substrate is quadrangular in shape, and at least one semiconductor element which constitutes a memory chip and a control chip for controlling the memory chip are fixed to the bottom of the groove to form a memory card.

22. An electronic device according to claim 19, wherein the substrate has a semiconductor element fixing area for fixing thereto of the semiconductor element, the semiconductor element fixing area being recessed, and the semiconductor element is fixed to a bottom of the recess.

23. An electronic device according to claim 19, wherein a semiconductor element is fixed stackedly in at least one stage onto the semiconductor element fixed to the groove bottom in such a manner that the overlying semiconductor element is displaced so as to permit exposure of electrodes formed on the semiconductor elements, and the electrodes are electrically connected to the wiring lines through the connecting means.

24. A method of manufacturing an electronic device, comprising the steps of:
providing a substrate, the substrate having unit substrate areas arranged in order lengthwise and crosswise, with a plurality of external electrode terminals being exposed to a first surface of the substrate in each of the unit substrate areas, the substrate also having a groove formed in a second surface as a back surface opposite to the first surface or in the first surface in the direction of arrangement of the external electrode terminals and throughout the overall length of the substrate, the substrate further having wiring lines;
fixing at least one semiconductor element to a bottom of the groove in each of the unit substrate areas of the substrate;
connecting electrodes on the semiconductor element and the wiring lines electrically with each other through a connecting means;
filling up the groove with an insulating resin so as to cover the semiconductor element and the connecting means, thereby forming a sealing member; and
separating the substrate and the sealing member for each of the unit substrate areas.

25. A method according to claim 24, wherein a surface of the sealing member is formed flat, the flat surface being substantially flush with substrate surface portions located on both sides of the groove.

26. A method according to claim 24, wherein the substrate is quadrangular in shape, and at least one semiconductor element which constitutes a memory chip and a control chip for controlling the memory chip are fixed to the bottom of the groove in each of the unit substrate areas to form a memory card.

27. A method according to claim 24, wherein a recess is formed in the groove bottom of the substrate and the semiconductor element is fixed to a bottom of the recess.

28. A method according to claim 24, wherein a semiconductor element is fixed stackedly in at least one stage onto the semiconductor element fixed to the groove bottom in such a manner that the electrodes formed on the underlying semiconductor element are exposed, and thereafter the electrodes on the semiconductor elements and the wiring lines are electrically connected with each other through the connecting means.

29. An electronic device comprising:
a substrate having wiring lines with a plurality of external electrode terminals exposed to a first surface of the substrate;
a groove formed in a second surface as a back surface opposite to the first surface or in the first surface in the direction of arrangement of the external electrode terminals and throughout the overall length of the substrate;
a sealing member formed of an insulating resin, the sealing member being buried in the groove so as to fill up a part of the groove;
at least one semiconductor element covered with the sealing member, fixed to a bottom of the groove, and having electrodes connected electrically to the wiring lines through a connecting means; and
at least one semiconductor element fixed to the groove portion not covered with the sealing member and having electrodes connected electrically to the wiring lines through a connecting means.

30. An electronic device according to claim 29, wherein a surface of the semiconductor element fixed to the groove portion not covered with the sealing member and on which the electrodes are formed confronts the groove bottom, the electrodes are electrically connected with the wiring lines on the groove bottom through an anisotropic conductive adhesive, and the surface of the semiconductor element does not project from substrate surface portions located on both sides of the groove.

31. An electronic device according to claim 29, wherein a surface of the semiconductor element fixed to the groove portion not covered with the sealing portion and on which the electrodes are formed confronts the groove bottom, the electrodes are electrically connected with the wiring lines on the groove bottom, an under-fill resin is filled between the groove bottom and the semiconductor element, and the surface of the semiconductor element does not project from substrate surface portions located on both sides of the groove.

32. An electronic device according to claim 29, wherein the substrate is quadrangular in shape, and at least one semiconductor element which constitutes a memory chip and a control chip for controlling the memory chip are fixed to the substrate to form a memory card.

33. A method of manufacturing an electronic device, comprising the steps of:
providing a substrate, the substrate having unit substrate areas arranged in order lengthwise and crosswise, with a plurality of external electrode terminals being exposed to a first surface of the substrate in each of the unit substrate areas, the substrate also having a groove formed in a second surface opposite to the first surface or in the first surface in the direction of arrangement of the external electrode terminals and throughout the overall length of the substrate, the substrate further having wiring lines;
fixing at least one semiconductor element to a bottom of the groove in each of the unit substrate areas of the substrate at an offset position;
connecting electrodes on the semiconductor element and the wiring lines electrically with each other through a connecting means;
filling up a part of the groove with an insulating resin so as to cover the semiconductor element and the connecting means, thereby forming a sealing member;
fixing a semiconductor element to a groove bottom portion not covered with the sealing portion and connecting electrodes formed on the semiconductor element electrically with the wiring lines through a connecting means; and
separating the substrate and the sealing member for each of the unit substrate areas.

34. A method according to claim 33, wherein a surface of a semiconductor element on which surface are formed electrodes is set face to face with the groove bottom portion not covered with the sealing member, and the electrodes on the semiconductor element and wiring lines located on the groove bottom are connected with each other mechanically and electrically while interposing an anisotropic conductive adhesive between the groove bottom and the semiconductor element.

35. A method according to claim 33, wherein a surface of a semiconductor element on which surface are formed electrodes is set face to face with the groove bottom portion not covered with the sealing member, and wiring lines located on the groove bottom and the electrodes on the semiconductor element are bonded together through solder.

36. A method according to claim 33, wherein the substrate is quadrangular in shape, and at least one semiconductor element which constitutes a memory chip and a control chip for controlling the semiconductor chip are fixed to the substrate in each of the unit substrate areas to form a memory card.

37. An electronic device comprising:
a substrate having wiring lines with a plurality of external electrode terminals exposed to a first surface of the substrate;
a sealing member formed of an insulating resin to cover the whole of a second surface as a back surface opposite to the first surface;
a groove formed in the first surface of the substrate in the direction of arrangement of the external electrode terminals and throughout the overall length of the substrate;
a sealing member formed of an insulating resin, the sealing member being buried in the groove to fill up the groove; and
at least one semiconductor element disposed in each of the sealing members so as to be covered with the sealing member, the semiconductor element being fixed to the substrate and having electrodes formed thereon, the electrodes being connected electrically to the wiring lines through a connecting means.

38. An electronic device according to claim 37, wherein the sealing members each have a flat surface which is substantially flush with substrate surface portions located on both sides of the groove.

39. An electronic device according to claim 37, wherein the substrate is quadrangular in shape, and at least one semiconductor element which constitutes a memory chip and a control chip for controlling the memory chip are fixed to the substrate to form a memory card.

40. A method of manufacturing an electronic device, comprising the steps of:
providing a substrate, the substrate having unit substrate areas arranged in order lengthwise and crosswise, with a plurality of external electrode terminals being exposed to a first surface of the substrate in each of the unit substrate areas, the substrate also having a groove formed in the first surface in the direction of arrangement of the external electrode terminals and throughout the overall length of the substrate, the substrate further having wiring lines;
fixing at least one semiconductor element to a bottom of the groove in each of the unit substrate areas of the substrate;
fixing at least one semiconductor element to a second surface as a back surface opposite to the first surface of the substrate in each of the unit substrate areas;
connecting electrodes formed on each of the semiconductor elements and the wiring lines with each other through a connecting means;
burying an insulating resin in the groove to fill up the groove, thereby forming a sealing member which covers the semiconductor elements and the connecting means, forming a sealing member throughout the whole of the second surface of the substrate with use of an insulating resin so as to cover the semiconductor element on the second surface and the connecting means; and
separating the substrate and the sealing member for each of the unit substrate areas.

41. A method according to claim 40, wherein surfaces of the sealing members are formed flat, and the surface of the sealing member formed to fill up the groove is formed so as to be substantially flush with substrate surface portions located on both sides of the groove.

42. A method according to claim 40, wherein the substrate and the sealing members are formed in a quadrangular shape, and at least one semiconductor element which constitutes a memory chip and a control chip for controlling the memory chip are fixed to the substrate in each of the unit substrate areas to form a memory card.

43. An electronic device comprising:
a case having a recess formed in one surface thereof; and
a COB package fitted in and bonded to the recess, the COB package comprising:
a substrate having wiring lines with a plurality of external electrode terminals exposed to a first surface of the substrate;
a groove formed in a second surface as a back surface opposite to the first surface of the substrate or in the first surface in the direction of arrangement of the external electrode terminals and throughout the overall length of the substrate;
a sealing member formed of an insulating resin, the sealing member being buried in the groove to fill up the groove; and
at least one semiconductor element covered with the sealing member, fixed to a bottom of the groove, and having electrodes connected electrically to the wiring lines through a connecting means,
the COB package being bonded to the case so that the external electrode terminals are exposed.

44. An electronic device according to claim 43, wherein at least one semiconductor element which constitutes a memory chip and a control chip for controlling the memory chip are fixed to the substrate.

45. An electronic device according to claim 43, wherein a direction recognizing portion is formed at an edge of the case.

46. An electronic device comprising:
a case having a recess formed in one surface thereof; and
a COB package fitted in and bonded to the recess, the COB package comprising:
a substrate having wiring lines with a plurality of external electrode terminals exposed to a first surface of the substrate;
a groove formed in a second surface as a back surface of the first surface or in the first surface in the direction of arrangement of the external electrode terminals and throughout the overall length of the substrate;
a sealing member formed of an insulating resin, the sealing member being buried in the groove to fill up the groove;
at least one semiconductor element covered with the sealing member, fixed to a bottom of the groove, and having electrodes connected electrically to the wiring lines through a connecting means; and
at least one semiconductor element fixed to the groove portion not covered with the sealing portion and having electrodes connected electrically to the wiring lines through a connecting means,
the COB package being bonded to the case so that the external electrode terminals are exposed.

47. An electronic device according to claim 46, wherein at least one semiconductor element which constitutes a memory chip and a control chip for controlling the memory chip are fixed to the substrate to form a memory card.

48. An electronic device according to claim 46, wherein a direction recognizing portion is formed at an edge of the case.

49. An electronic device, comprising:
a case having a recess formed in one surface thereof; and
a COB package fitted in and bonded to the recess, the COB package comprising:
a substrate having wiring lines with a plurality of external electrode terminals exposed to a first surface of the substrate;
a sealing member formed of an insulating resin to cover the whole of a second surface as a back surface opposite to the first surface;
a groove formed in the first surface in the direction of arrangement of the external electrode terminals and throughout the overall length of the substrate;
a sealing member formed of an insulating resin, the sealing member being buried in the groove to fill up the groove; and
at least one semiconductor element provided in each of the sealing members so as to be covered with the sealing member, the semiconductor element being fixed to the substrate and having electrodes connected electrically to the wiring lines through a connecting means,
the COB package being bonded to the case so that the external electrode terminals are exposed.

50. An electronic device according to claim 49, wherein at least one semiconductor element which constitutes a memory chip and a control chip for controlling the memory chip are fixed to the substrate.

51. An electronic device according to claim 49, wherein a direction recognizing portion is formed at an edge of the case.
